(19) United States
(12) Patent Application Publication
(10) Pub. No.: US 2020/0105808 A1
(43) Pub. Date: Apr. 2, 2020

(54) SOLID-STATE IMAGING DEVICE AND ELECTRONIC APPARATUS

(71) Applicant: Sony Semiconductor Solutions Corporation, Kanagawa (JP)

(72) Inventors: Yukio Tagawa, Tokyo (JP); Koji Yoshikawa, Kanagawa (JP); Yuhi Yorikado, Kanagawa (JP); Koichi Baba, Kanagawa (JP)

(73) Assignee: Sony Semiconductor Solutions Corporation, Kanagawa (JP)

(21) Appl. No.: 16/500,571

(22) PCT Filed: Apr. 2, 2018
(86) PCT No.: PCT/JP2018/014066

§ 371 Date: Oct. 3, 2019

(30) Foreign Application Priority Data
Apr. 11, 2017 (JP) 2017-078183
Aug. 10, 2017 (JP) 2017-155550

(51) Int. Cl. H01L 27/146

(52) U.S. Cl. CPC H01L 27/14616; H01L 27/14643

(57) ABSTRACT

An imaging device is provided includes a plurality of pixels (200-1). A pixel (200-1) of the plurality of pixels includes: a first wiring coupled to a floating diffusion (221); a second wiring opposed to the first wiring such that a wiring capacitance (Cfd-vsl) is formed; a pixel amplifier (214) with a feedback capacitance that is based on the wiring capacitance; and a vertical signal line (22) arranged to output a signal from the floating diffusion. The wiring capacitance is formed between the floating diffusion and the vertical signal line.

### TECHNICAL FIELD

The present technology relates to a solid-state imaging device and an electronic apparatus, and particularly to a solid-state imaging device and an electronic apparatus that are capable of reducing variation in conversion efficiency.

### CROSS REFERENCE TO RELATED APPLICATIONS

This application claims the benefit of Japanese Priority Patent Application JP 2017-078183 filed Apr. 11, 2017, the entire contents of which are incorporated herein by reference.

### BACKGROUND ART

In recent years, a CMOS (Complementary Metal Oxide Semiconductor) image sensor has become widespread. In the CMOS image sensor, a source follower pixel reading circuit is widely used as a circuit for reading signal charges photoelectrically converted by a plurality of pixels arranged in a pixel array unit.

Further, examples of a circuit for reading signal charges with high conversion efficiency include a source-grounded pixel reading circuit and a differential pixel reading circuit. For example, the technology disclosed in Japanese Patent Application Laid-open No. 2005-278041 is known as a technology relating to conversion efficiency by reading at source-ground.

### SUMMARY OF INVENTION

### Technical Problem

Meanwhile, in the source-grounded pixel reading circuit or the differential pixel reading circuit, although signal charges can be read with higher conversion efficiency than that in the source follower pixel reading circuit, variation in conversion efficiency is large. Therefore, a technology for reducing the variation is desired.

The present technology has been made in view of the above circumstances to make it possible to reduce variation in conversion efficiency while reading signal charges with high conversion efficiency.

### Solution to Problem

According to some aspects, an imaging device is provided. The imaging device includes a plurality of pixels. A pixel of the plurality of pixels includes: a first wiring coupled to a floating diffusion; a second wiring opposed to the first wiring such that a wiring capacitance is formed; a pixel amplifier with a feedback capacitance that is based on the wiring capacitance; and a vertical signal line arranged to output a signal from the floating diffusion. The wiring capacitance is formed between the floating diffusion and the vertical signal line.

According to some aspects, an imaging device is provided. The imaging device includes a plurality of pixels. A pixel of the plurality of pixels includes:

a first wiring coupled to a floating diffusion; a second wiring opposed to the first wiring such that a wiring capacitance is formed; a pixel amplifier with a feedback capacitance that is based on the wiring capacitance;

a vertical signal line arranged to output a signal from the floating diffusion; a first transistor comprising a source and a drain; and a second transistor comprising a source and a drain, wherein the source of the second transistor is coupled to an output of the pixel amplifier and the drain of the second transistor is coupled to the vertical signal line. The wiring capacitance is formed between the floating diffusion and the source of the second transistor.

According to some aspects, an imaging device is provided. The imaging device includes a plurality of pixels. A pixel of the plurality of pixels includes: a first wiring coupled to a floating diffusion; a second wiring opposed to the first wiring such that a wiring capacitance is formed; a pixel amplifier with a feedback capacitance that is based on the wiring capacitance;

a vertical signal line arranged to output a signal from the floating diffusion; a first transistor comprising a source and a drain; a second transistor comprising a source and a drain, wherein the source of the second transistor is coupled to an output of the pixel amplifier and the drain of the second transistor is coupled to the vertical signal line; and a third transistor comprising a source and a drain, wherein the source of the third transistor is coupled to the floating diffusion and the drain of the third transistor is coupled to a reset line. The wiring capacitance is formed between the floating diffusion and the drain of the third transistor.

According to some aspects, an amplifier that includes a transistor is provided. The transistor includes a gate and an asymmetric source-drain structure. The asymmetric source-drain structure includes a source region comprising: a first region including an impurity with a first concentration; and a second region including an impurity with a second concentration larger than the first concentration. The asymmetric source-drain structure also includes a drain region comprising: a third region including an impurity with a third concentration larger than the first concentration.

An imaging device and an electronic apparatus according to an aspect of the present technology may be an independent apparatus, or may be an internal block constituting one apparatus.

### Advantageous Effects of Invention

In accordance with an aspect of the present technology, it is possible to reduce variation in conversion efficiency.

It should be noted that the effect described here is not necessarily limitative and may be any effect described in the present disclosure.

These and other objects, features and advantages of the present disclosure will become more apparent in light of the following detailed description of best mode embodiments thereof, as illustrated in the accompanying drawings.

### BRIEF DESCRIPTION OF DRAWINGS

FIG. 1 is a diagram showing a configuration example of an embodiment of a solid-state imaging device to which the present technology is applied.

FIG. 2 is a diagram describing conversion efficiency of a pixel amplifier.

FIG. 3 is a diagram describing a feedback capacitance including a parasitic capacitance of an amplification transistor.

FIG. 4 is a diagram describing a relationship between conversion efficiency of a pixel to which a differential pixel amplifier is applied and output variation in a read signal (PRNU).

FIG. 5 is a circuit diagram showing a configuration example of a source-grounded inversion amplification pixel amplifier.

FIG. 6 is a circuit diagram showing a configuration example of a differential inversion amplification pixel amplifier.

FIG. 7 is a circuit diagram showing a configuration example of a pixel amplifier that performs reading in a differential mode.

FIG. 8 is a circuit diagram showing a configuration example of a pixel amplifier that performs reading in an SF mode.

FIG. 9 is a circuit diagram describing a wiring capacitance between FD-VSL of a type 1.

FIG. 10 is a top view describing an opposite wiring between FD-VSL of the type 1 by the same metal layer.

FIG. 11 is a top view describing an opposite wiring between FD-VSL of the type 1 by different metal layers.

FIG. 12 is a circuit diagram describing a wiring capacitance between FD-VSL of a type 2.

FIG. 13 is a top view describing an opposite wiring between FD-VSL of the type 2 by the same metal layer.

FIG. 14 is a top view describing an opposite wiring between FD-VSL of the type 2 by different metal layers.

FIG. 15 is a circuit diagram describing a wiring capacitance between FD-VSL of a type 3.

FIG. 16 is a top view describing an opposite wiring between FD-VSL of the type 3 by the same metal layer.

FIG. 17 is a top view describing an opposite wiring between FD-VSL of the type 3 by different metal layers.

FIG. 18 is a diagram describing capacitance variation between opposite wirings.

FIG. 19 is a cross-sectional view showing a structural example of a general amplification transistor.

FIG. 20 is a cross-sectional view showing a first structural example of an amplification transistor to which an embodiment of the present technology is applied.

FIG. 21 is a diagram for comparing structures of amplification transistors.

FIG. 22 is a diagram showing a structural example of an amplification transistor having different channel widths on the drain side and the source side.

FIG. 23 is a cross-sectional diagram showing a first example of a second structure of the amplification transistor to which an embodiment of the present technology is applied.

FIG. 24 is a diagram describing a first example of a method of producing the amplification transistor.

FIG. 25 is a cross-sectional diagram showing a second example of the second structure of the amplification transistor to which an embodiment of the present technology is applied.

FIG. 26 is a diagram describing a second example of a method of producing the amplification transistor.

FIG. 27 is a cross-sectional diagram showing a third example of the second structure of the amplification transistor to which an embodiment of the present technology is applied.

FIG. 28 is a diagram describing a third example of a method of producing the amplification transistor.

FIG. 29 is a diagram describing an effect depending on the flowing direction of current in the amplification transistor.

FIG. 30 is a cross-sectional view showing another example of the structure of the amplification transistor.

FIG. 31 is a circuit diagram showing another configuration example of a differential inversion amplification pixel amplifier.

FIG. 32 is a block diagram showing a configuration example of an electronic apparatus including a solid-state imaging device to which an embodiment of the present technology is applied.

FIG. 33 is a diagram showing a usage example of the solid-state imaging device to which an embodiment of the present technology is applied.

FIG. 34 is a block diagram showing a schematic configuration example of a vehicle control system.

FIG. 35 is an explanatory diagram showing examples of mounting positions of a vehicle exterior information detection unit and image capture units.

### DESCRIPTION OF EMBODIMENTS

Hereinafter, embodiments of the technology according to the present disclosure (the present technology) will be described with reference to the drawings. Note that descriptions will be made in the following order.

1. Configuration of Solid-state imaging device

2. Overview of Present Technology

3. Configuration Example of Pixel Amplifier
(1) Source-grounded Inversion Amplification Pixel Amplifier
(2) Differential Inversion Amplification Pixel Amplifier

4. Wiring Capacitance between FD-VSL
(1) Type 1
(2) Type 2
(3) Type 3

5. First Structural Example of Amplification Transistor

6. Second Structural Example of Amplification Transistor

7. Modified Example

8. Configuration of Electronic Apparatus

9. Usage Example of Solid-state Imaging Device

10. Example of Application to Movable Object

### 1. Configuration of Solid-State Imaging Device

(Configuration Example of Solid-State Imaging Device)

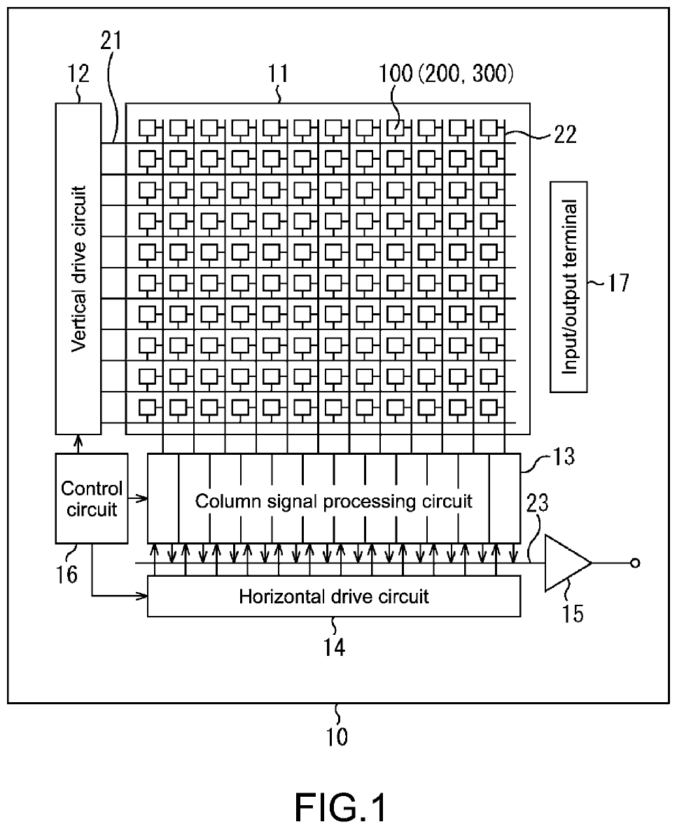

FIG. 1 is a diagram showing a configuration example of an embodiment of a solid-state imaging device to which the present technology is applied.

A CMOS image sensor 10 shown in FIG. 1 is an example of a solid-state imaging device using a CMOS (Complementary Metal Oxide Semiconductor). The CMOS image sensor 10 captures incident light (image light) from a subject via an optical lens system (not shown), converts the light amount of the incident light imaged on an imaging surface into electric signals in units of pixels, and outputs the electric signals as pixel signals.

In FIG. 1, the CMOS image sensor 10 includes a pixel array unit 11, a vertical drive circuit 12, a column signal processing circuit 13, a horizontal drive circuit 14, an output circuit 15, a control circuit 16, and an input/output terminal 17.

In the pixel array unit 11, a plurality of pixels 100 are arranged two-dimensionally (in a matrix). The pixel 100 includes a photodiode (PD) as a photoelectric conversion unit and a plurality of pixel transistors. For example, the pixel transistor includes a transfer transistor (Trg-Tr), a reset transistor (Rst-Tr), an amplification transistor (AMP-Tr), and a selection transistor (Sel-Tr).

Note that as the pixels arranged in the pixel array unit 11, pixels 200 or pixels 300 can be arranged in addition to the pixels 100. However, the detailed content thereof will be described later.

The vertical drive circuit 12 includes, for example, a shift register, selects a predetermined pixel drive line 21, supplies a pulse for driving the pixels 100 to the selected pixel drive line 21, and drives the pixels 100 row by row. Specifically, the vertical drive circuit 12 sequentially selects and scans each pixel 100 in the pixel array unit 11 in the vertical direction row by row, and supplies a pixel signal based on the signal charge (charge) generated depending on the amount of received light in the photodiode of each pixel 100 to the column signal processing circuit 13 through a vertical signal line 22.

The column signal processing circuit 13 is arranged for each column of the pixels 100, and performs, for each pixel column, signal processing such as noise removal on signals output from the pixels 100 in one row. For example, the column signal processing circuit 13 performs signal processing such as correlated double sampling (CDS) for removing fixed pattern noise unique to the pixel and AD (Analog Digital) conversion.

The horizontal drive circuit 14 includes, for example, a shift register, sequentially selects each of the column signal processing circuits 13 by sequentially outputting a horizontal scanning pulse, and causes each of the column signal processing circuits 13 to output a pixel signal to a horizontal signal line 23.

The output circuit 15 performs signal processing on the signal sequentially supplied from each of the column signal processing circuits 13 through the horizontal signal line 23, and outputs the processed signal. Note that the output circuit 15 performs, for example, only buffering, or black level adjustment, column variation correction, various types of digital signal processing, and the like in some cases.

The control circuit 16 controls the operation of the respective units of the CMOS image sensor 10.

Further, the control circuit 16 generates a clock signal and a control signal, which are used as the reference of the operation of the vertical drive circuit 12, the column signal processing circuit 13, the horizontal drive circuit 14, and the like, on the basis of a vertical synchronous signal, a horizontal synchronous signal, and a master clock signal. The control circuit 16 outputs the generated clock signal and control signal to the vertical drive circuit 12, the column signal processing circuit 13, the horizontal drive circuit 14, and the like.

The input/output terminal 17 transmits/receives signals to/from the outside.

The CMOS image sensor 10 in FIG. 1 configured as described above is a CMOS image sensor called a column AD method in which the column signal processing circuits 13 that perform CDS processing and AD conversion processing are arranged for each pixel column. Further, the CMOS image sensor 10 in FIG. 1 may be, for example, a backside irradiation type CMOS image sensor.

### 2. Overview of Present Technology

A high-gain inversion amplification pixel amplifier such as a source-grounded pixel amplifier and a differential pixel amplifier has a larger gain as compared with a source follower pixel amplifier whose conversion efficiency is determined by the floating diffusion (FD) capacitance, and it is possible to greatly increase the conversion efficiency.

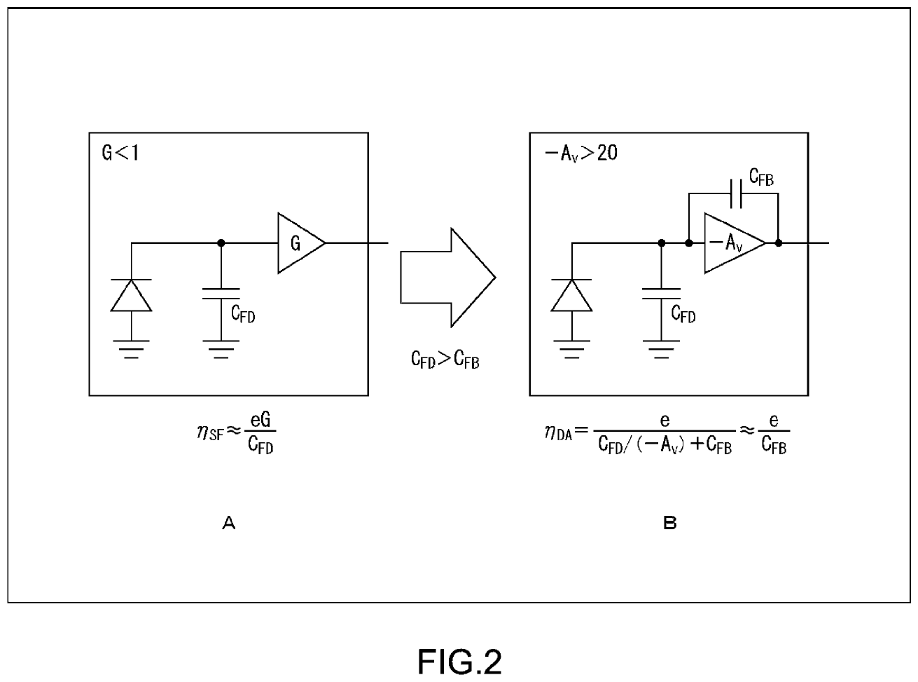

Note that FIG. 2 shows conversion efficiency of a source follower pixel amplifier and a high-gain inversion amplification pixel amplifier.

As shown in FIG. 2A, in the source follower pixel amplifier, a gain G satisfies the relationship of G<1, and conversion efficiency η_{sF} thereof is represented by the following formula (1).

$$\begin{matrix}[ Math . 1 ] & \\ {η}_{SF} \approx \frac{eG}{{C}_{FD}} & ( 1 )\end{matrix}$$

Note that in the formula (1), C_{FD} represents the FD capacitance. Although conversion efficiency can be improved by reducing the FD capacitance, there is a limit to reduce the FD capacitance.

Meanwhile, as shown in FIG. 2B, in the high-gain inversion amplification pixel amplifier, an open loop gain Av satisfies the relationship of (−Av)>20, and conversion efficiency η_{DA} thereof is represented by the following formula (2).

$$\begin{matrix}[ Math . 2 ] & \\ {η}_{high \text{-} gain} = \frac{e}{{C}_{FD} / ( - {A}_{v} ) + {C}_{FB}} \approx \frac{e}{{C}_{FB}} & ( 2 )\end{matrix}$$

Note that in the formula (2), C_{FD} and C_{FB} respectively represent the FD capacitance and the feedback capacitance component included in the C_{FD}. Note that since C_{FD}/(−Av)<<C_{FB}, the conversion efficiency is substantially determined by the feedback capacitance C_{FB}. Further, since C_{FD}=C_{FD-Other}+C_{FB}>C_{FB}, conversion efficiency higher than that in the existing source follower pixel amplifier can be achieved.

Since the high-gain inversion amplification pixel amplifier has such characteristics, a CMOS image sensor with ultrahigh SN ratio (Signal to Noise Ratio) can be achieved. However, variation in conversion efficiency due to variation in the feedback capacitance C_{FB} that determines the conversion efficiency is larger than that in the source follower pixel amplifier.

Note that conversion efficiency η of a differential pixel amplifier as the high-gain inversion amplification pixel amplifier is represented by the following formula (3) by using the open loop gain Av, the feedback capacitance C_{FB}, and the FD capacitance C_{FD}.

$$\begin{matrix}[ Math . 3 ] & \\ η ( differential ) = \frac{e}{{C}_{FD} / ( - {A}_{v} ) + {C}_{FB}} \approx \frac{e}{{C}_{FB}} & ( 3 )\end{matrix}$$

In the formula (3), the feedback capacitance C_{FB} mainly includes the parasitic capacitance of the amplification transistor (AMP-Tr). Therefore, since the feedback capacitance C_{FB} can be smaller than the FD capacitance C_{FD} as the total gate capacitance of the amplification transistor (AMP-Tr), the reset transistor (Rst-Tr), and the transfer transistor (Trg-Tr) connected to an FD diffusion layer, an FD wiring capacitance, and an FD terminal, high conversion efficiency can be achieved.

Meanwhile, in the differential pixel amplifier having high conversion efficiency, variation in signal output due to variation in conversion efficiency increases.

Note that variation in the output signal (ΔV_{VSL}) of the vertical signal line (VSL) provided in the column direction of the pixels arranged two-dimensionally (in a matrix) in the pixel array unit is generally represented by the amount PRNU (Photo Response Non Uniformity) shown in the following formula (4).

$$\begin{matrix} [ Math . 4 ] & \\ PRNU ≡ \frac{{σ}_{Δ {V}_{VSL}}}{〈 Δ {V}_{VSL} 〉} = \sqrt{\frac{{σ}_{Δ {V}_{VSL}}^{2}}{{〈 Δ {V}_{VSL} 〉}^{2}}} = \sqrt{\frac{{σ}_{η \cdot N}^{2}}{{〈 η \cdot N 〉}^{2}}} = \sqrt{\frac{{σ}_{η}^{2} \cdot {σ}_{N}^{2}}{{〈 η 〉}^{2} \cdot {〈 N 〉}^{2}} + \frac{{σ}_{η}^{2}}{{〈 η 〉}^{2}} + \frac{{σ}_{N}^{2}}{{〈 N 〉}^{2}}} & ( 4 )\end{matrix}$$

Note that ΔV_{VSL} and σΔV_{VSL} respectively represent variation in the output signal (ΔV_{VSL}) in the vertical signal line (VSL) and the standard deviation thereof, and < > represents the expected value.

As shown in the formula (4), the variation in the output signal (ΔV_{VSL}) can be divided into a fluctuation component (σ_{N}) of the signal charge number (N), which includes optical shot noise, pixel optical system fluctuation, and photoelectric conversion fluctuation, and a fluctuation component (σ_{η}) of the conversion efficiency at the time of reading.

Further, in the PRNU with a small light amount in which the optical shot noise is small, variation in characteristics of the pixels themselves becomes dominant and particularly, the fluctuation component (σ_{η}) of the conversion efficiency is larger than the fluctuation component (σ_{N}) of the signal charge number in the high-gain pixel with high conversion efficiency. Therefore, the relationship represented by the formula (5) is established.

$$\begin{matrix}[ Math . 5 ] & \\ PRNU \approx \frac{{σ}_{η}}{〈 η 〉} \approx \frac{{σ}_{{C}_{FB}}^{2}}{{〈 {C}_{FB} 〉}^{2}} & ( 5 )\end{matrix}$$

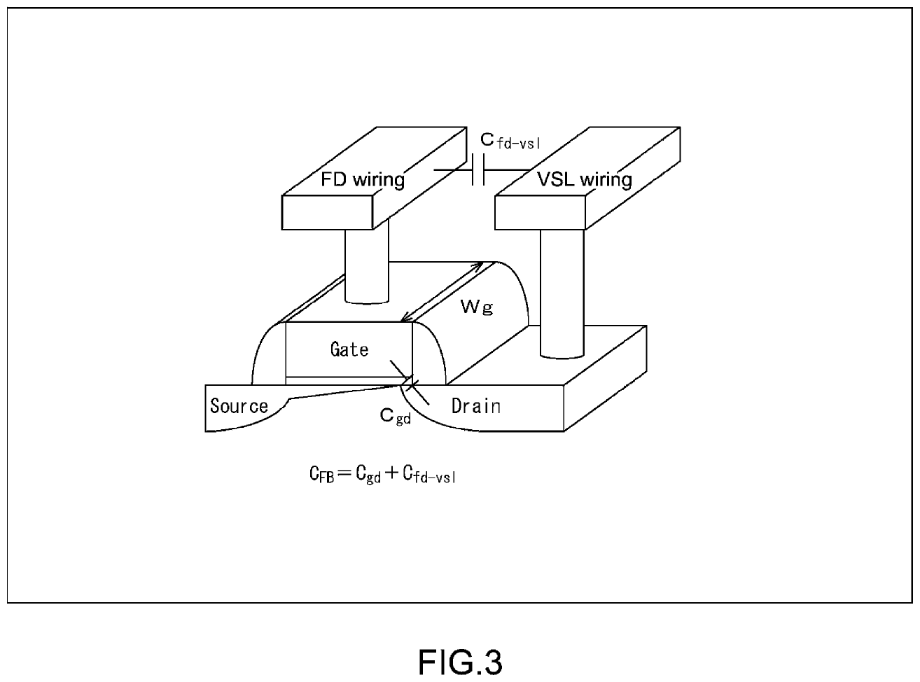

In the formula (5), the feedback capacitance C_{FB} mainly includes a component of a drain-side overlap capacitance C_{gd} of the amplification transistor (AMP-Tr) and a component of a wiring capacitance C_{fd-vsl} between the floating diffusion node (FD node) and the vertical signal line (VSL). In FIG. 3, the periphery of the amplification transistor (AMP-Tr) is schematically shown. The relationship between the three capacitances (C_{FB}, C_{gd}, and C_{fd-vsl}) is represented by the following formula (6).

[Math. 6]

C_{FB}=C_{gd}+C_{fd-vsl} (6)

Note that in the formula (6), particularly, the drain-side overlap capacitance C_{gd} of the amplification transistor (AMP-Tr), which is the main component, mainly includes the gate overlap capacitance of the amplification transistor (AMP-Tr). Therefore, the drain-side overlap capacitance C_{gd} of the amplification transistor (AMP-Tr) is substantially proportional to a gate width Wg, and the variation thereof is represented by σ_{Cgd}/<C_{gd}>∝Wg^{-1/2}.

Meanwhile, in fine pixels, it is necessary to narrow the gate width Wg of the amplification transistor (AMP-Tr) on the layout. In the case where a differential pixel amplifier is applied thereto, although the conversion efficiency becomes very large, variation in the conversion efficiency increases. Note that the fine pixels are, for example, fine pixels used in a CMOS image sensor or the like for a mobile terminal.

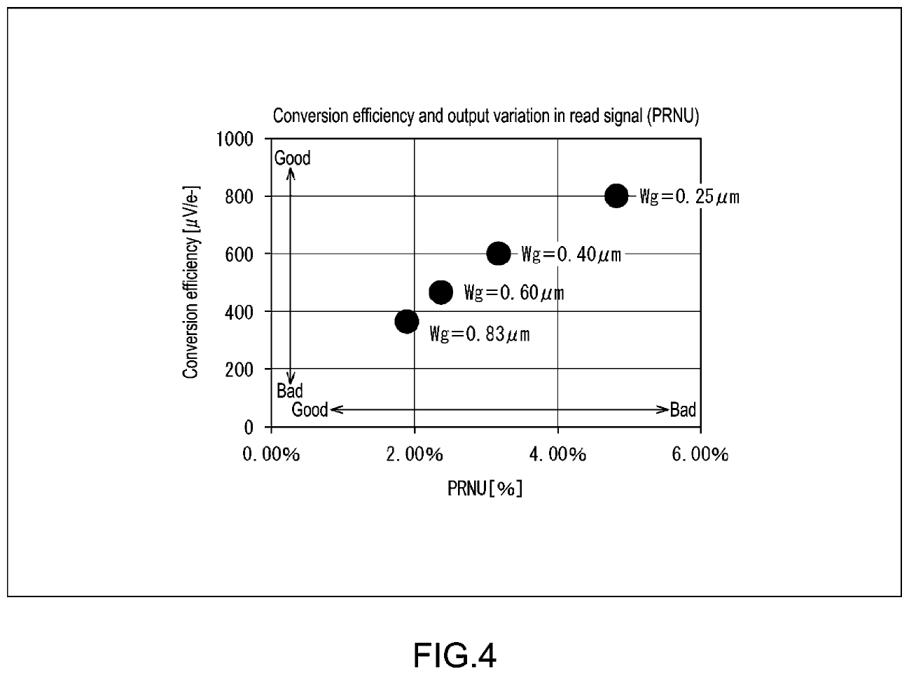

FIG. 4 is a diagram describing a relationship between conversion efficiency of a pixel to which a differential pixel amplifier is applied and output variation in a read signal (output signal of the vertical signal line (VSL)) (PRNU). Note that in FIG. 4, the horizontal axis represents PRNU (%), and the vertical axis represents conversion efficiency (μV/e−).

FIG. 4 represents that as the gate width Wg of the amplification transistor (AMP-Tr) becomes narrower, the conversion efficiency increases and PRNU becomes larger. That is, there is a trade-off relationship between increasing the conversion efficiency and improving PRNU by narrowing the gate width Wg (narrowing Wg).

That is, in fine pixels, there is no degree of freedom in adjusting the gate width Wg of the amplification transistor (AMP-Tr) on the layout, which makes it difficult to optimize the conversion efficiency.

Therefore, in the present technology, the capacitance C_{fd-vsl} of opposite long wirings connected between the floating diffusion (FD) and the vertical signal line (VSL) is added to the feedback capacitance C_{FB} of the differential pixel amplifier including the overlap capacitance C_{gd} of the amplification transistor (AMP-Tr) as a main component, thereby adjusting the conversion efficiency of the differential pixel amplifier and dispersing the variation factors to reduce the variation in the feedback capacitance C_{FB}.

At this time, the above-mentioned formula (5) can be represented as the following formula (7).

$$\begin{matrix}[ Math . 7 ] & \\ {PRNU}^{2} \approx \frac{{σ}_{η}^{2}}{{〈 η 〉}^{2}} \approx \frac{{σ}_{{C}_{FB}}^{2}}{{〈 {C}_{FB} 〉}^{2}} = \frac{{σ}_{{C}_{gd}}^{2} + {σ}_{{C}_{fd \text{-} vsl}}^{2}}{{\{ 〈 {C}_{gd} 〉 + 〈 {C}_{fd \text{-} vsl} 〉 \}}^{2}} & ( 7 )\end{matrix}$$

Further, since the effect of reducing the variation is reduced in the case where the variation in the capacitance C_{fd-vsl} added between the floating diffusion (FD) and the vertical signal line (VSL) is larger than the variation in the overlap capacitance C_{gd} of the amplification transistor (AMP-Tr), the capacitance C_{fd-vsl} is formed with opposite wirings whose capacitance variation is small, in the present technology.

Hereinafter, the content of the present technology will be described with reference to specific embodiments.

### 3. Configuration Example of Pixel Amplifier

(1) Source-grounded Inversion Amplification Pixel Amplifier

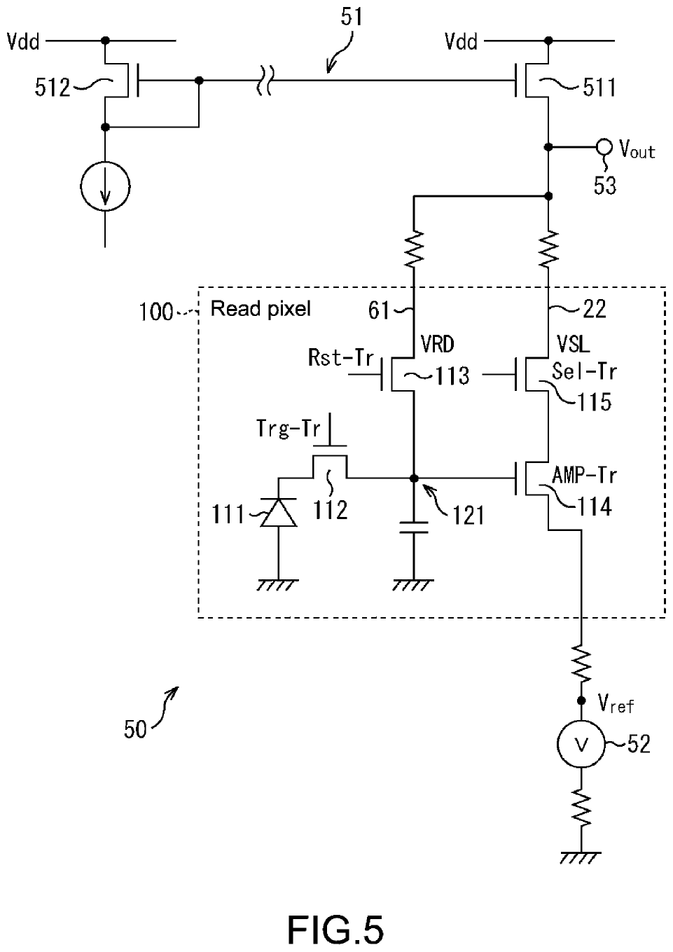

FIG. 5 is a diagram showing a configuration example of a source-grounded inversion amplification pixel amplifier.

In FIG. 5, a source-grounded pixel reading circuit 50 having the function of a source-grounded inversion amplification pixel amplifier includes a read pixel 100 that reads a signal charge, a load MOS circuit 51 that supplies constant current to the pixel, and a constant voltage source 52 in which the voltage is constant. The load MOS circuit 51 includes PMOS transistors such as a PMOS transistor 511 and a PMOS transistor 512.

The read pixel 100 includes, for example, four pixel transistors of a transfer transistor 112, a reset transistor 113, an amplification transistor 114, and a selection transistor 115, in addition to a photoelectric conversion unit 111 such as a photodiode (PD).

In the photoelectric conversion unit 111, an anode electrode that is one end thereof is grounded, and a cathode electrode that is the other end is connected to the source of the transfer transistor 112. The drain of the transfer transistor 112 is connected to the source of the reset transistor 113 and the gate of the amplification transistor 114, and this connection point constitutes a floating diffusion 121 as a floating diffusion region.

The drain of the reset transistor 113 is connected to a vertical reset input line 61. The source of the amplification transistor 114 is connected to the constant voltage source 52. The drain of the amplification transistor 114 is connected to the source of the selection transistor 115, and the drain of the selection transistor 115 is connected to the vertical signal line 22.

To the gate of the transfer transistor 112, the gate of the reset transistor 113, and the gate of the selection transistor 115, the vertical drive circuit 12 (FIG. 1) are connected via the pixel drive line 21 (FIG. 1), and pulses as driving signals are supplied.

Note that the vertical signal line 22 is connected to the vertical reset input line 61, the drain of the PMOS transistor 511 in the load MOS circuit 51, and an output terminal 53 of the source-grounded pixel reading circuit 50. Further, the vertical reset input line 61 is connected to the vertical signal line 22.

In the source-grounded pixel reading circuit 50 having the above-mentioned configuration, the amplification transistor 114 constitutes a source-grounded inversion amplifier together with the PMOS transistor 511, and thus, a voltage signal corresponding to the signal charge detected by the photoelectric conversion unit 111 is output via the output terminal 53.

(2) Differential Inversion Amplification Pixel Amplifier

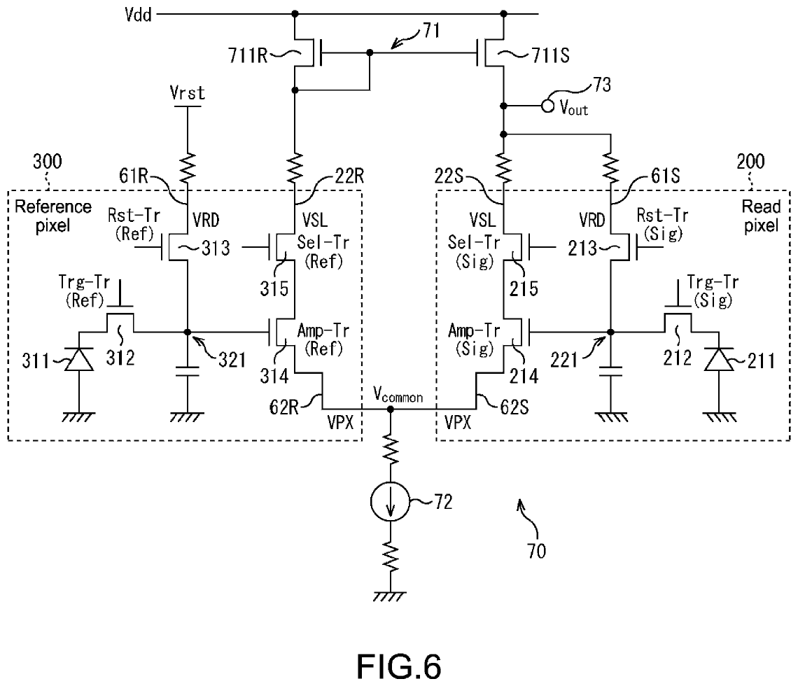

FIG. 6 is a diagram showing a configuration example of a source-grounded differential inversion amplification pixel amplifier.

In FIG. 6, a differential pixel reading circuit 70 having the function of a source-grounded differential inversion amplification pixel amplifier includes a read pixel 200 that reads a signal charge, a reference pixel 300 that gives reference voltage without a signal charge, a current mirror circuit 71 that includes a PMOS transistor, and a load MOS circuit 72 that supplies constant current to the pixel.

The read pixel 200 includes, for example, four pixel transistors of a transfer transistor 212, a reset transistor 213, an amplification transistor 214, and a selection transistor 215, in addition to a photoelectric conversion unit 211 such as a photodiode (PD).

In the photoelectric conversion unit 211, an anode electrode that is one end thereof is grounded, and a cathode electrode that is the other end is connected to the source of the transfer transistor 212. The drain of the transfer transistor 212 is connected to the source of the reset transistor 213 and the gate of the amplification transistor 214, and this connection point constitutes a floating diffusion 221 as a floating diffusion region.

The drain of the reset transistor 213 is connected to a reading-side vertical reset input line 61S. The source of the amplification transistor 214 is connected to a reading-side vertical current supply line 62S. The drain of the amplification transistor 214 is connected to the source of the selection transistor 215, and the drain of the selection transistor 215 is connected to a reading-side vertical signal line 22S.

To the gate of the transfer transistor 212, the gate of the reset transistor 213, and the gate of the selection transistor 215, the vertical drive circuit 12 (FIG. 1) is connected via the pixel drive line 21 (FIG. 1), and pulses as driving signals are supplied.

Note that the reading-side vertical signal line 22S is connected to the reading-side vertical reset input line 61S, the drain of a reading-side PMOS transistor 711S in the current mirror circuit 71, and an output terminal 73 of the differential pixel reading circuit 70.

Further, the reading-side vertical reset input line 61S is connected to the reading-side vertical signal line 22S, and to the floating diffusion 221 of the selected read pixel 200, i.e., the input terminal of the amplification transistor 214, and the output signal of the differential pixel reading circuit 70 is negatively fed back when the reset transistor 213 is being on.

The reference pixel 300 includes, for example, four pixel transistors of a transfer transistor 312, a reset transistor 313, an amplification transistor 314, and a selection transistor 315, in addition to a photoelectric conversion unit 311 such as a photodiode (PD).

In the photoelectric conversion unit 311, an anode electrode that is one end thereof is grounded, and a cathode electrode that is the other end is connected to the source of the transfer transistor 312. The drain of the transfer transistor 312 is connected to the source of the reset transistor 313 and the gate of the amplification transistor 314, and this connection point constitutes a floating diffusion 321 as a floating diffusion region.

The drain of the reset transistor 313 is connected to a reference-side vertical reset input line 61R. The source of the amplification transistor 314 is connected to a reference-side vertical current supply line 62R. The drain of the amplification transistor 314 is connected to the source of the selection transistor 315, and the drain of the selection transistor 315 is connected to a reference-side vertical signal line 22R.

To the gate of the transfer transistor 312, the gate of the reset transistor 313, and the gate of the selection transistor 315, the vertical drive circuit 12 (FIG. 1) is connected via the pixel drive line 21 (FIG. 1), and pulses as driving signals are supplied.

Note that the reference-side vertical signal line 22R is connected to the drain and gate of a reference-side PMOS transistor 711R in the current mirror circuit 71, and to the gate of the reading-side PMOS transistor 711S.

Further, the reference-side vertical reset input line 61R is connected to a predetermined power source Vrst, and a desired input voltage signal is applied to the floating diffusion 321 of the selected reference pixel 300, i.e., the input terminal of the amplification transistor 314 via the wiring at the time of resetting.

Note that the reference pixel 300 is desirably a pixel in which the potential fluctuation of the terminal (FD terminal) of the floating diffusion 321 at the time of resetting is equivalent to the potential fluctuation of the terminal (FD terminal) of the floating diffusion 221 of the read pixel 200. For example, as the reference pixel 300, an inactive effective pixel that has finished reading and is arranged in the vicinity of the read pixel 200 in the pixel array unit 11 (FIG. 1) can be used. In this case, the roles of the read pixel 200 and the reference pixel 300 in FIG. 6 are switched by the switched provided in the column signal processing circuit 13 (FIG. 1).

The reading-side vertical current supply line 62S and the reference-side vertical current supply line 62R are connected to the load MOS circuit 72 that is a constant current source after being connected to each other at a connection point (V_{common}).

In the differential pixel reading circuit 70 having the above-mentioned configuration, the amplification transistor 214 of the read pixel 200 and the amplification transistor 314 of the reference pixel 300 constitute a differential amplifier, and thus, a voltage signal corresponding to the signal charge detected by the photoelectric conversion unit 211 of the read pixel 200 is output via the output terminal 73.

(Configuration where Differential Mode and SF Mode Can Be Switched)

Incidentally, for differential reading, it is desirable to perform, for example, source-follower-type reading with a large dynamic range in the light state, because high conversion efficiency can be achieved. That is, in some cases, more appropriate reading can be performed by appropriately switching differential reading (hereinafter, referred to as the differential mode) and source-follower-type reading (hereinafter, referred to as the SF mode).

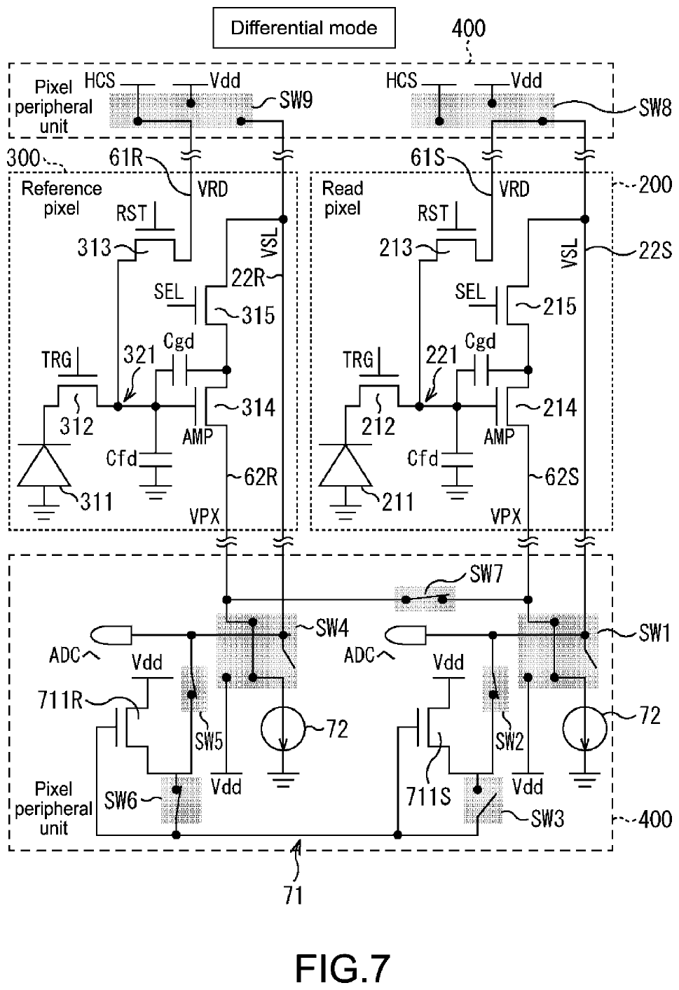

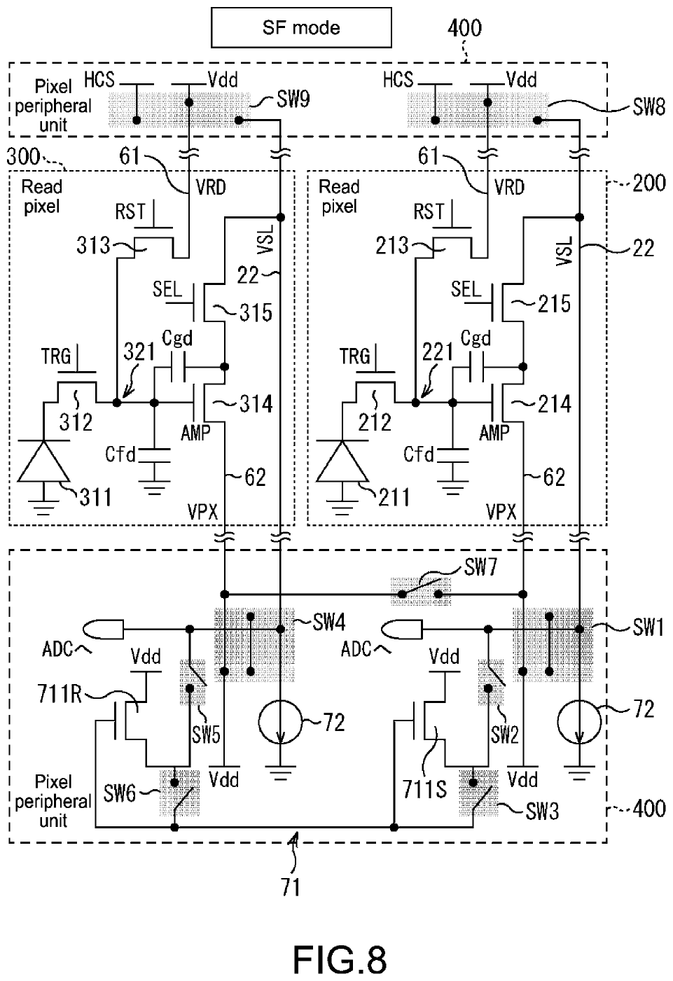

In this regard, next, a configuration where reading in the differential mode and reading in the SF mode can be switched will be described with reference to FIG. 7 and FIG. 8.

(Differential Mode)

FIG. 7 is a circuit diagram showing a configuration example of a pixel amplifier that performs reading in the differential mode.

In FIG. 7, the read pixel 200 is configured similarly to the read pixel 200 shown in FIG. 6, and also the reading-side vertical signal line 22S, the reading-side vertical reset input line 61S, and the reading-side vertical current supply line 62S are connected in a similar way to the connection form shown in FIG. 6.

Further, in FIG. 7, the reference pixel 300 is configured similarly to the reference pixel 300 shown in FIG. 6, and also the reference-side vertical signal line 22R, the reference-side vertical reset input line 61R, and the reference-side vertical current supply line 62R are connected in a similar way to the connection form shown in FIG. 6. Note that the reference pixel 300 is an equivalent effective pixel close to the read pixel 200, and is a pixel for determining differential reference voltage.

Note that in FIG. 7, a pixel peripheral unit 400 is provided for the read pixel 200 and the reference pixel 300. Switches SW1 to SW9 are provided in the pixel peripheral unit 400. The switches SW1 to SW9 perform a switching operation, thereby switching reading in the differential mode and reading in the SF mode.

Specifically, in the case of performing reading in the differential mode, the switch SW1 performs a switching operation on the read pixel 200, thereby connecting the reading-side vertical current supply line 62S connected to the source of the amplification transistor 214 to the load MOS circuit 72. Further, the switch SW8 performs a switching operation on the read pixel 200, thereby connecting the reading-side vertical reset input line 61S to the reading-side vertical signal line 22S.

Further, in the case of performing reading in the differential mode, the switch SW4 performs a switching operation on the reference pixel 300, thereby connecting the reference-side vertical current supply line 62R connected to the source of the amplification transistor 314 to the load MOS circuit 72. Further, the switch SW9 performs a switching operation on the reference pixel 300, thereby connecting the reference-side vertical reset input line 61R to the reference-side vertical signal line 22R.

The pixel peripheral unit 400 includes the current mirror circuit 71 including the reading-side PMOS transistor 711S and the reference-side PMOS transistor 711R.

In the pixel peripheral unit 400, the switch SW2 and the switch SW3 perform a switching operation, thereby connecting the reading-side vertical signal line 22S to the drain of the reading-side PMOS transistor 711S in the current mirror circuit 71. Meanwhile, in the pixel peripheral unit 400, the switch SW5 and the switch SW6 perform a switching operation, thereby connecting the reference-side vertical signal line 22R to the drain and gate of the reference-side PMOS transistor 711R in the current mirror circuit 71 and to the gate of the reading-side PMOS transistor 711S. Note that in the case of performing reading in the differential mode, the switch SW7 is in an on-state.

As described above, the switches SW1 to SW9 of the pixel peripheral unit 400 perform a switching operation, and thus, the amplification transistor 214 of the read pixel 200 and the amplification transistor 314 of the reference pixel 300 constitute a differential amplifier. Accordingly, the reading in the differential mode is performed. As a result, a voltage signal corresponding to the signal charge detected by the photoelectric conversion unit 211 of the read pixel 200 is output to an AD converter (ADC) of the column signal processing circuit 13 (FIG. 1) via the reading-side vertical signal line 22S (and the output terminal 73).

Further, by switching the switches SW1 to SW9 of the pixel peripheral unit 400, the read pixel 200 and the reference pixel 300 can be switched. Therefore, it is possible to read all the pixels arranged in the pixel array unit 11 without increasing the number of unnecessary pixels.

Note that the case where the read pixel 200 and the reference pixel 300 are horizontally arranged in the same row in the pixel array unit 11 in the configuration of the pixel amplifier that performs the reading in the differential mode shown in FIG. 7 has been illustrated. However, the arrangement relationship between the read pixel 200 and the reference pixel 300 is arbitrary e.g., the read pixel 200 and the reference pixel 300 can be vertically arranged in the same column.

(SF Mode)

FIG. 8 is a circuit diagram showing a configuration example of a pixel amplifier that performs reading in the SF mode.

In FIG. 8, the read pixel 200, the read pixel 300, and the pixel peripheral unit 400 are configured in a similar way to the configuration shown in FIG. 7. However, the switches SW1 to SW9 of the pixel peripheral unit 400 perform a switching operation, and thus, the operation mode is switched from the differential mode to the SF mode.

Specifically, in the case of performing reading in the SF mode, the switch SW1 performs a switching operation on the read pixel 200, thereby connecting the reading-side vertical current supply line 62 connected to the source of the amplification transistor 214 to a power source voltage Vdd, and the vertical signal line 22 to the load MOS circuit 72. Further, the switch SW8 performs a switching operation on the read pixel 200, thereby connecting the vertical reset input line 61 to the power source voltage Vdd.

Similarly, in the case of performing reading in the SF mode, the switch SW4 performs a switching operation on the pixel 300, thereby connecting the reading-side vertical current supply line 62 connected to the source of the amplification transistor 314 to the power source voltage Vdd, and the vertical signal line 22 to the load MOS circuit 72. Further, the switch SW9 performs a switching operation on the pixel 300, thereby connecting the vertical reset input line 61 to the power source voltage Vdd.

Further, in the pixel peripheral unit 400, the switches SW2 and SW3 and the switches SW5 and SW6 perform a switching operation, and thus, the connection between the reading-side PMOS transistor 711S and the reference-side PMOS transistor 711R is released, and the current mirror circuit 71 for the differential mode is disconnected. Note that in the case of performing reading in the SF mode, the switch SW7 is in an off-state.

As described above, the switches SW1 to SW9 of the pixel peripheral unit 400 perform a switching operation, and thus, the amplification transistor 214 of the read pixel 200 and the amplification transistor 314 of the pixel 300 constitute a source follower inversion amplifier separately (for each column), and the reading in the SF mode is performed. As a result, a voltage signal corresponding to the signal charge detected by the photoelectric conversion unit 211 (311) of the read pixel 200 (300) is output to an AD converter (ADC) of the column signal processing circuit 13 (FIG. 1) via the vertical signal line 22.

As described above, the switches SW1 to SW9 perform a switching operation in the pixel peripheral unit 400, and thus, the reading in the differential mode and the reading in the SF mode can be easily switched. For example, in the light state, it is possible to switch to the source-follower-type reading with a large dynamic range.

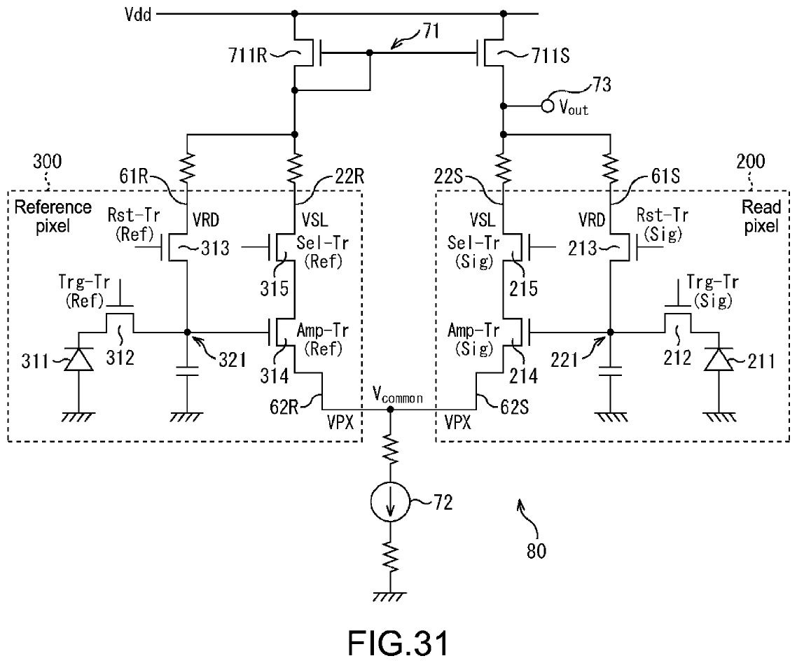

Note that although the configuration corresponding to the differential pixel reading circuit 70 shown in FIG. 6 has been illustrated as the configuration of the reading in the differential mode in FIG. 7, it may be a configuration similar to that of a differential pixel reading circuit 80 shown in FIG. 31 to be described later.

### 4. Wiring Capacitance Between FD-VSL

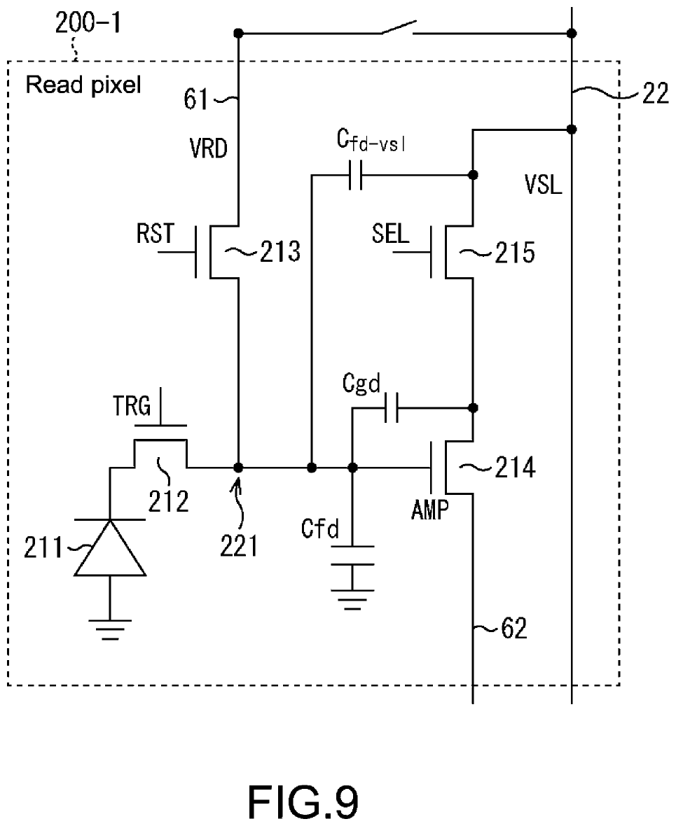

Next, the wiring capacitance C_{fd-VSL} between the floating diffusion (FD) and the vertical signal line (VSL) in the source-grounded inversion amplification pixel amplifier (FIG. 5) or the differential inversion amplification pixel amplifier (FIG. 6) will be described with reference to FIGS. 9 to 17.

In the present technology, by adding the wiring capacitance C_{fd-VSL} with the opposite wiring of the FD wiring connected to the floating diffusion (FD) and the VSL wiring connected to the vertical signal line (VSL), the feedback capacitance C_{FB} is adjusted. Here, as an example of the capacitance addition by the opposite wiring, three configurations of the type 1 to the type 3 will be illustrated.

That is, as shown in the above-mentioned formula (6), the feedback capacitance C_{FB} that determines the conversion efficiency includes the drain-side overlap capacitance C_{gd} of the amplification transistor 114 (214) and the wiring capacitance C_{fd-vsl}. Further, the wiring capacitance C_{fd-vsl} is classified into three types depending on the portion where the wiring capacitively connected to the FD wiring is electrically connected to the vertical signal line 22 at the time of reading.

Note that although the configuration of the read pixel 200 (FIG. 6, FIG. 7) will be described as an example in the following description, also the read pixel 100 (FIG. 5) or the reference pixel 300 (FIG. 6, FIG. 7) can employ a configuration similar thereto.

(1) Type 1

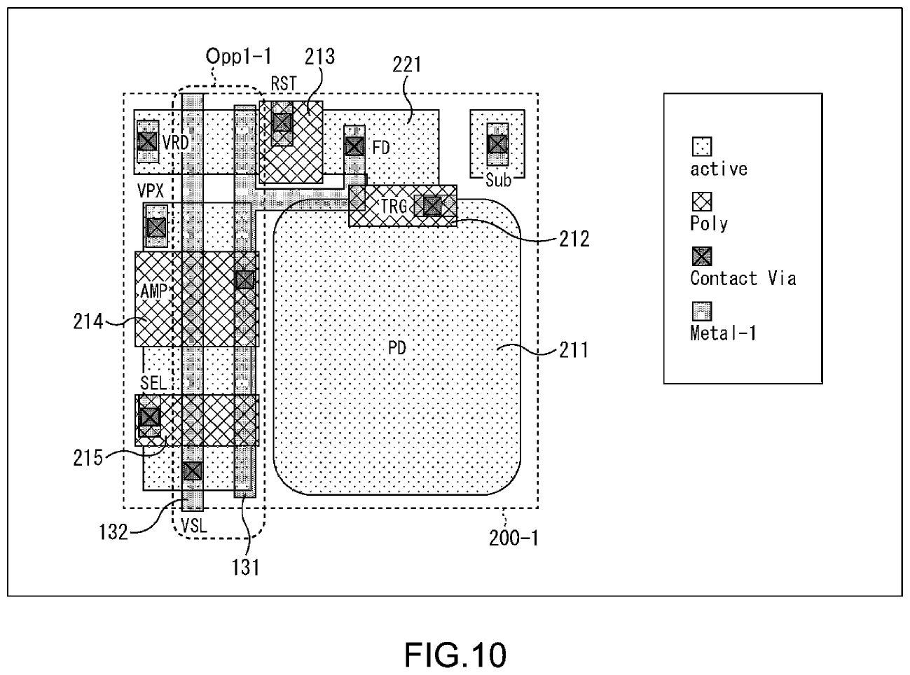

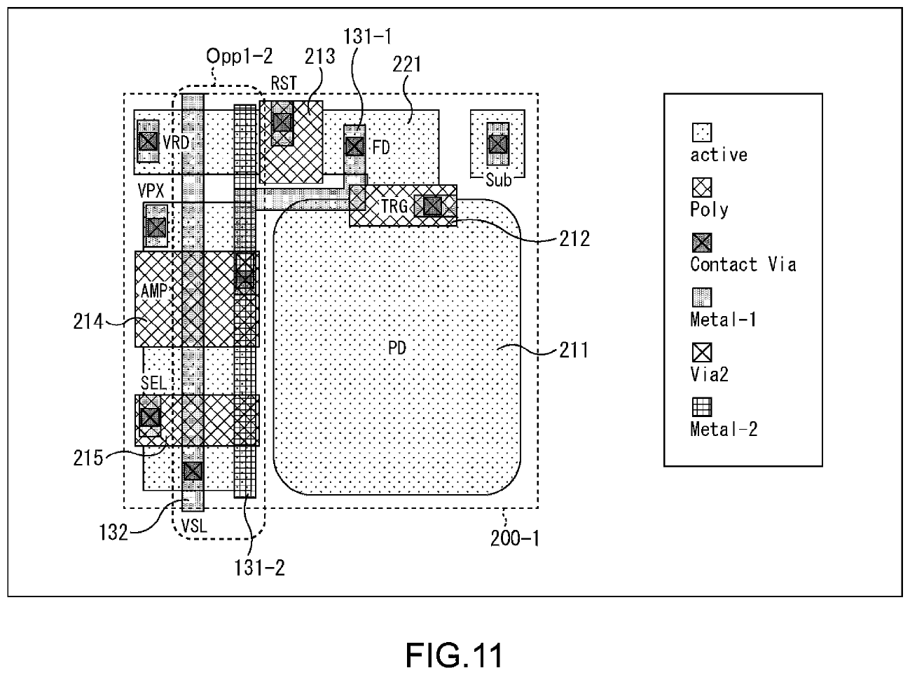

First, the wiring capacitance between FD-VSL of the type 1 will be described with reference to FIGS. 9 to 11. Note that FIG. 9 is a circuit diagram showing a read pixel 200-1, and FIG. 10 and FIG. 11 are each a plan view showing the layout of each device of the read pixel 200-1.

(Circuit Configuration)

FIG. 9 is a circuit diagram showing a pixel to which the wiring capacitance between FD-VSL of the type 1 is added.

In the read pixel 200-1 shown in FIG. 9, the capacitance addition is performed with the wiring capacitance C_{fd-vsl} of the opposite wiring connected to the electrode of the floating diffusion 221 (FD electrode) and the vertical signal line 22.

This capacitance addition makes it possible to disperse the feedback capacitance C_{FB} of the pixel amplifier into two components of the drain-side overlap capacitance C_{gd} and the wiring capacitance C_{fd-vsl}. As a result, it is possible to suppress the variation in the feedback capacitance C_{FB}.

Further, in the wiring capacitance between FD-VSL of the type 1, since it does not need to form a contact between the drain of the amplification transistor 214 and the source of the selection transistor 215, it is advantageous in terms of pixel layout as compared with the type 2 to be described later.

(Opposite Wiring Between FD-VSL by Same Metal Layer)

FIG. 10 is a plan view showing the layout of the opposite wiring between FD-VSL of the type 1 by the same metal layer.

In the read pixel 200-1 shown in FIG. 10, the capacitance addition is performed with the wiring capacitance C_{fd-vsl} by an opposite wiring Opp1-1 connected to the electrode of the floating diffusion 221 (FD electrode) and the vertical signal line 22.

That is, in the read pixel 200-1 shown in FIG. 10, the wiring capacitance C_{fd-vsl} is added by the opposite wiring Opp1-1 of an FD wiring 131 connected to the floating diffusion 221 and a VSL wiring 132 connected to the vertical signal line 22, and thus, the feedback capacitance C_{FB} is adjusted.

Further, in the read pixel 200-1 shown in FIG. 10, the FD wiring 131 and the VSL wiring 132 are formed on the same metal layer (Metal-1).

As described above, by making the FD wiring 131 and the VSL wiring 132 formed on the same metal layer (Metal-1), it is possible to suppress the variation due to misalignment of the photomask at the time of production. Further, in adding a desired capacitance value, in the opposite wiring Opp1-1 of the FD wiring 131 and the VSL wiring 132, the degree of averaging increases and the variation is reduced by increasing the distance at a certain distance to reduce the capacitance per unit facing length and increasing the length of the opposite wiring by the amount corresponding thereto.

(Opposite Wiring Between FD-VSL by Different Metal Layers)

FIG. 11 is a plan view showing the layout of the opposite wiring between FD-VSL of the type 1 by different metal layers.

Of the FD wirings connected to the floating diffusion 221 in the read pixel 200-1 shown in FIG. 11, an FD wiring 131-1 is formed on a first metal layer (Metal-1) and an FD wiring 131-2 is formed on a second metal layer (Metal-2). Further, the VSL wiring 132 connected to the vertical signal line 22 is formed on the first metal layer (Metal-1). That is, the FD wiring 131-2 and the VSL wiring 132 are formed on different metal layers.

Then, by an opposite wiring Opp1-2 of the FD wiring 131-2 connected to the floating diffusion 221 and the VSL wiring 132 connected to the vertical signal line 22, the wiring capacitance C_{fd-vsl} is added, and the feedback capacitance C_{FB} is adjusted.

As described above, for example, even in the case where the opposite wiring Opp1-2 cannot be formed on the same metal layer on the pixel layout, by decreasing the overlapping of the metal to be opposed, increasing the distance between the FD wiring 131-2 and the VSL wiring 132 of the opposite wiring Opp1-2 at a certain distance, and increasing the length of the opposite wirings at the time of production, it is possible to achieve an effect similar to that in the opposite wiring Opp1-1 in the same metal layer shown in FIG. 10.

(2) Type 2

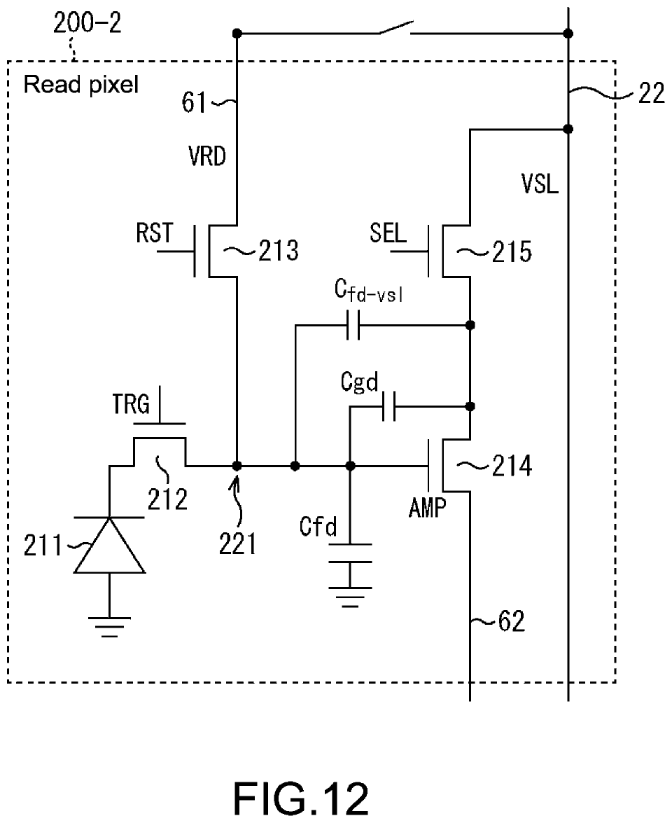

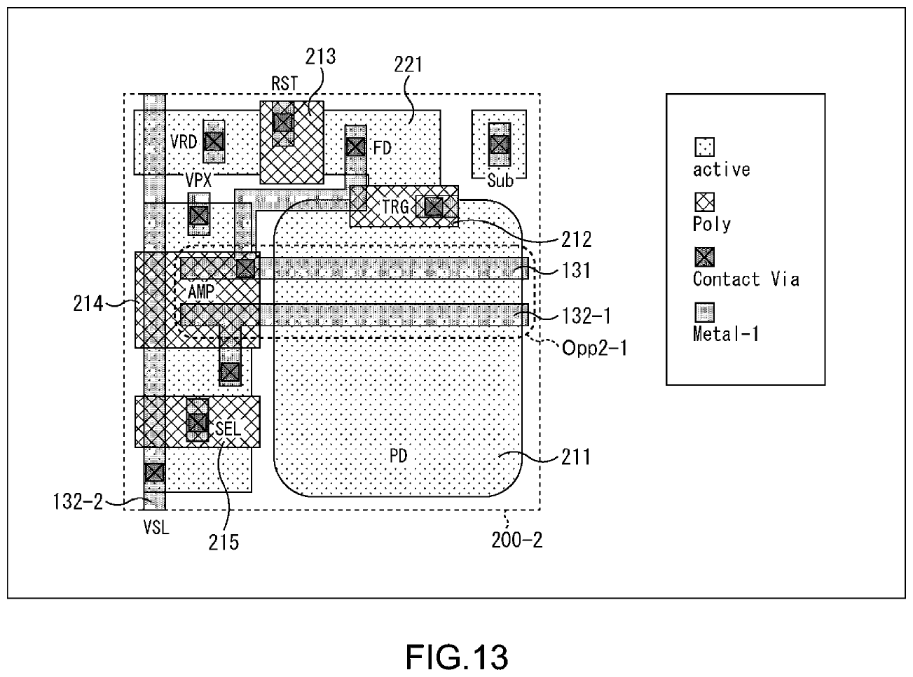

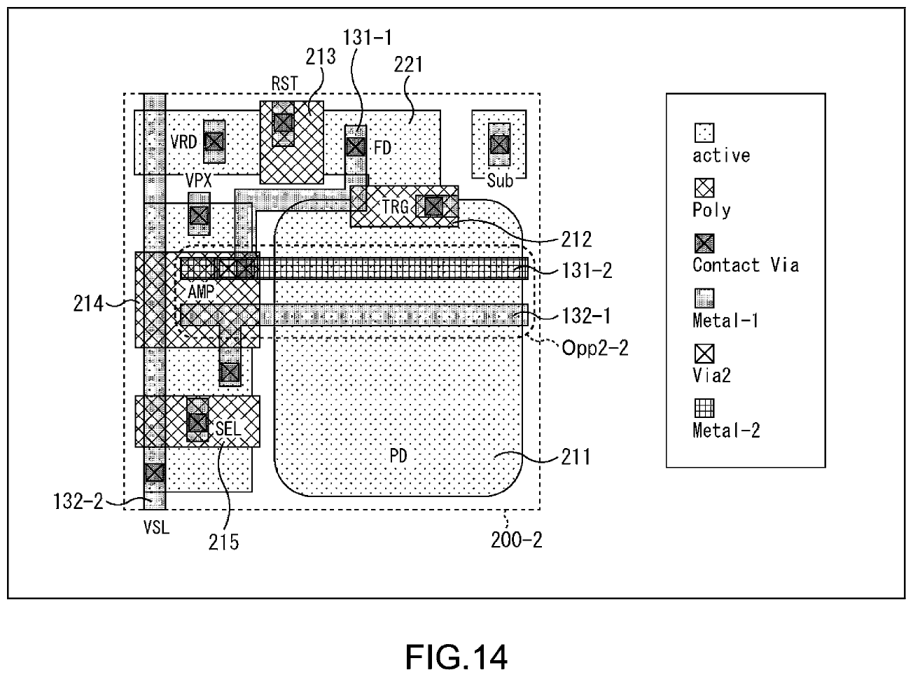

Next, the wiring capacitance between FD-VSL of the type 2 will be described with reference to FIGS. 12 to 14. Note that FIG. 12 is a circuit diagram showing a read pixel 200-2, and FIG. 13 and FIG. 14 are each a plan view showing the layout of each device of the read pixel 200-2.

(Circuit Configuration)

FIG. 12 is a circuit diagram showing a pixel to which the wiring capacitance between FD-VSL of the type 2 is added.

In the read pixel 200-2 shown in FIG. 12, the capacitance addition is performed with the wiring capacitance C_{fd-vsl} by the opposite wirings connected to the electrode of the floating diffusion 221 (FD electrode) and the diffusion layer between the drain of the amplification transistor 214 and the source of the selection transistor 215 (between AMP-SEL).

By performing such capacitance addition, the capacitance added to the unselected pixel can be disconnected from the vertical signal line 22, and the variation in the feedback capacitance C_{FB} can be suppressed.

Further, in the wiring capacitance between FD-VSL of the type 2, although it is necessary to form a contact between the drain of the amplification transistor 214 and the source of the selection transistor 215, the added capacitance is disconnected from the vertical signal line 22 when the selection transistor 215 is turned off, as compared with the above-mentioned type 1. Therefore, it is possible to suppress the reduction in read speed due to the increase in the total capacitance of the vertical signal line 22.

(Opposite Wiring Between FD-VSL by Same Metal Layer)

FIG. 13 is a plan view showing the layout of the opposite wiring between FD-VSL of the type 2 by the same metal layer.

In the read pixel 200-2 shown in FIG. 13, the capacitance addition is performed with the wiring capacitance C_{fd-vsl} by an opposite wiring Opp2-1 connected to the electrode of the floating diffusion 221 (FD electrode) and the vertical signal line 22.

That is, in the read pixel 200-2 shown in FIG. 13, by the opposite wiring Opp2-1 of the FD wiring 131 connected to the floating diffusion 221 and a VSL wiring 132-1 (the VSL wiring 132-1 out of the VSL wiring 132-1 and a VSL wiring 132-2) connected to the vertical signal line 22, the wiring capacitance C_{fd-vsl} is added, and the feedback capacitance C_{FB} is adjusted.

Further, in the read pixel 200-2 shown in FIG. 13, the FD wiring 131, the VSL wiring 132-1, and the VSL wiring 132-2 are formed on the same metal layer (Metal-1).

As described above, by making the FD wiring 131 and the VSL wirings 132-1 and 132-2 formed on the same metal layer (Metal-1), it is possible to suppress the variation due to misalignment of the photomask at the time of production. Further, in adding a desired capacitance value, in the opposite wiring Opp2-1 of the FD wiring 131 and the VSL wiring 132-1, the degree of averaging increases and the variation is reduced by increasing the distance at a certain distance to reduce the capacitance per unit facing length and increasing the length of the opposite wiring by the amount corresponding thereto.

(Opposite Wiring Between FD-VSL by Different Metal Layers)

FIG. 14 is a plan view showing the layout of the opposite wiring between FD-VSL of the type 2 by different metal layers.

Of the FD wirings connected to the floating diffusion 221 in the read pixel 200-2 shown in FIG. 14, the FD wiring 131-1 is formed on the first metal layer (Metal-1) and the FD wiring 131-2 is formed on the second metal layer (Metal-2). Further, the VSL wiring 132-1 and the VSL wiring 132-2 connected to the vertical signal line 22 are both formed on the first metal layer (Metal-1). That is, the FD wiring 131-2 and the VSL wiring 132-1 are formed on different metal layers.

Then, by an opposite wiring Opp2-2 of the FD wiring 131-2 connected to the floating diffusion 221 and the VSL wiring 132-1 (the VSL wiring 132-1 out of the VSL wiring 132-1 and the VSL wiring 132-2) connected to the vertical signal line 22, the wiring capacitance C_{fd-vsl} is added, and the feedback capacitance C_{FB} is adjusted.

As described above, for example, even in the case where the opposite wiring Opp2-2 cannot be formed on the same metal layer on the pixel layout, by decreasing the overlapping of the metal to be opposed, increasing the distance between the FD wiring 131-2 and the VSL wiring 132-1 of the opposite wiring Opp2-2 at a certain distance, and increasing the length of the opposite wirings at the time of production, it is possible to achieve an effect similar to that in the opposite wiring Opp2-1 in the same metal layer shown in FIG. 13.

(3) Type 3

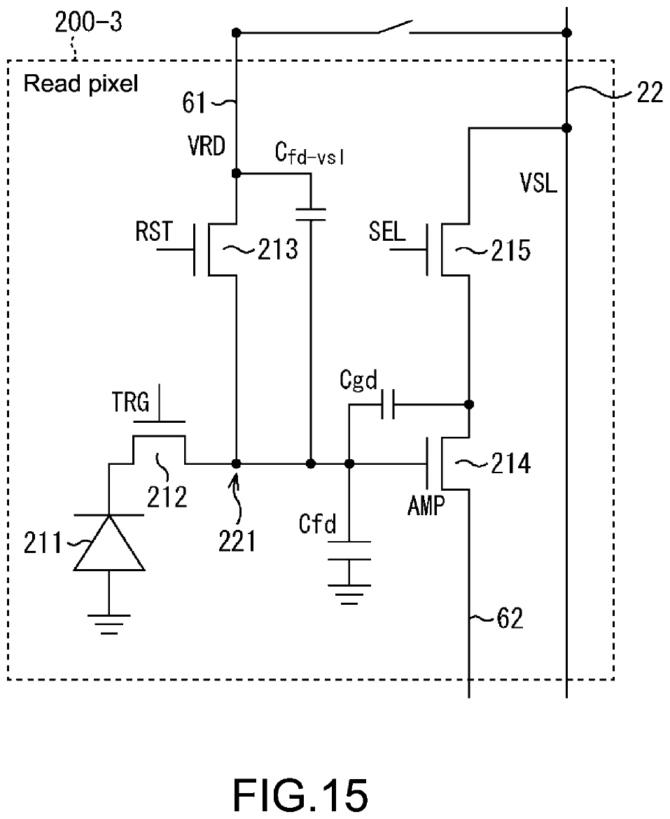

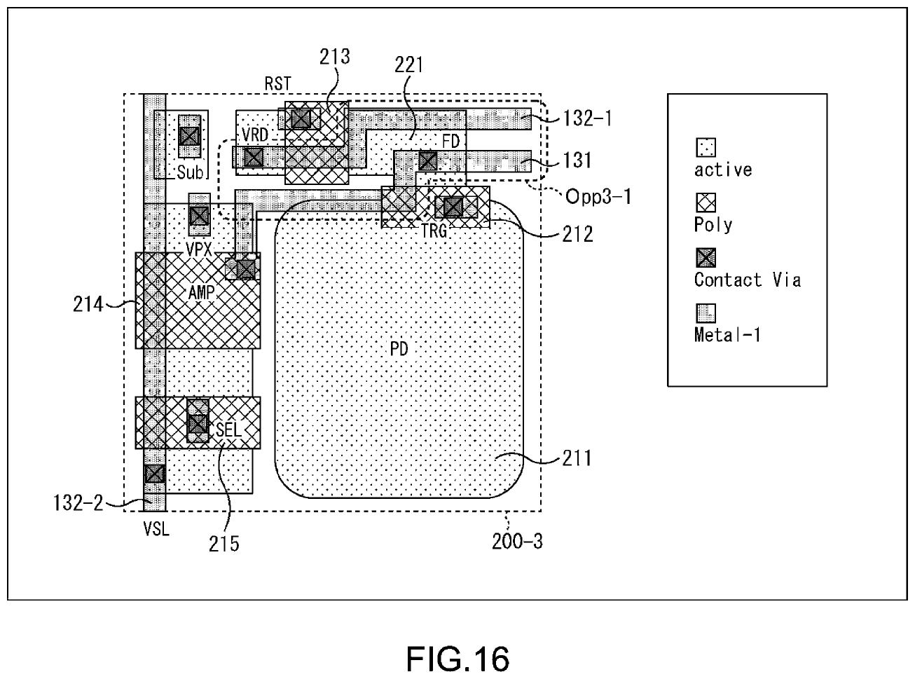

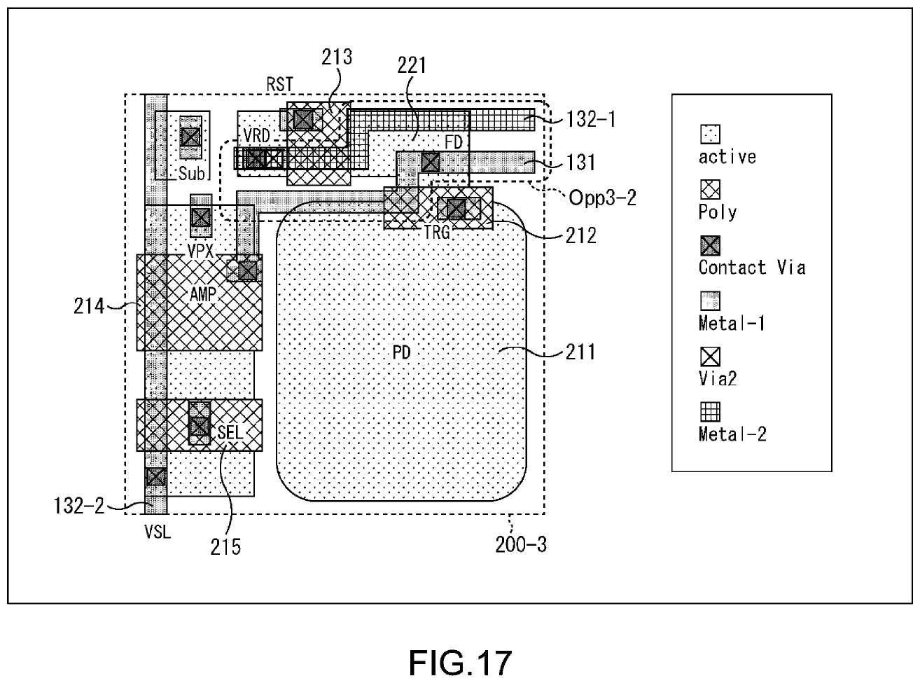

Finally, the wiring capacitance between FD-VSL of the type 3 will be described with reference to FIGS. 15 to 17. FIG. 15 is a circuit diagram showing a read pixel 200-3, and FIG. 16 and FIG. 17 are each a plan view showing the layout of each device of the read pixel 200-3.

(Circuit Configuration)

FIG. 15 is a circuit diagram showing a pixel to which the wiring capacitance between FD-VSL of the type 3 is added.

In the read pixel 200-3 shown in FIG. 15, the capacitance addition is performed with the wiring capacitance C_{fd-vsl} by the opposite wiring connected to the electrode of the floating diffusion 221 (FD electrode) and the drain-side electrode of the reset transistor 213. By performing such capacitance addition, it is possible to suppress the variation in the feedback capacitance C_{FB}.

Further, in the wiring capacitance between FD-VSL of the type 3, on/off control for disconnecting the wiring capacitance C_{fd-vsl} can be performed in the pixel peripheral portion. Therefore, the differential conversion efficiency can be switched, and there is also an advantage that the added capacitance of the inactive pixel is disconnected from the vertical signal line 22 when driving in the source follower mode (SF mode) to be described later.

(Opposite Wiring Between FD-VSL by Same Metal Layer)

FIG. 16 is a plan view showing the layout of the opposite wiring between FD-VSL of the type 3 by the same metal layer.

In the read pixel 200-3 shown in FIG. 16, capacitance addition is performed with the wiring capacitance C_{fd-vsl} by an opposite wiring Opp3-1 connected to the electrode of the floating diffusion 221 (FD electrode) and the vertical signal line 22.

That is, in the read pixel 200-3 shown in FIG. 16, by the opposite wiring Opp3-1 of the FD wiring 131 connected to the floating diffusion 221 and the VSL wiring 132-1 (the VSL wiring 132-1 out of the VSL wiring 132-1 and the VSL wiring 132-2) connected to the vertical signal line 22, the wiring capacitance C_{fd-vsl} is added, and the feedback capacitance C_{FB} is adjusted.

Further, in the read pixel 200-3 shown in FIG. 16, the FD wiring 131, the VSL wiring 132-1, and the VSL wiring 132-2 are formed on the same metal layer (Metal-1).

As described above, by making the FD wiring 131 and the VSL wirings 132-1 and 132-2 in the same metal layer (Metal-1), it is possible to suppress the variation due to misalignment of the photomask at the time of production. Further, in adding a desired capacitance value, in the opposite wiring Opp3-1 of the FD wiring 131 and the VSL wiring 132-1, the degree of averaging increases and the variation is reduced by increasing the distance at a certain distance to reduce the capacitance per unit facing length and increasing the length of the opposite wiring by the amount corresponding thereto.

(Opposite Wiring Between FD-VSL by Different Metal Layers)

FIG. 17 is a plan view showing the layout of the opposite wiring between FD-VSL of the type 3 by different metal layers.

In the read pixel 200-3 shown in FIG. 17, the FD wiring 131 connected to the floating diffusion 221 is formed on the first metal layer (Metal-1). Further, of the VSL wirings connected to the vertical signal line 22, the VSL wiring 132-1 is formed on the second metal layer (Metal-2), and the VSL wiring 132-2 is formed on the first metal layer (Metal-1). That is, the FD wiring 131 and the VSL wiring 132-1 are formed on different metal layers.

Then, by an opposite wiring Opp3-2 of the FD wiring 131 connected to the floating diffusion 221 and the VSL wiring 132-1 connected to the vertical signal line 22, the wiring capacitance C_{fd-vsl} is added, and the feedback capacitance C_{FB} is adjusted.

As described above, for example, even in the case where the opposite wiring Opp3-2 cannot be formed on the same metal layer on the layout, by decreasing the overlapping of the metal to be opposed, increasing the distance between the FD wiring 131 and the VSL wiring 132-1 of the opposite wiring Opp3-2 at a certain distance, and increasing the length of the opposite wirings at the time of production, it is possible to achieve an effect similar to that in the opposite wiring Opp3-1 in the same metal layer shown in FIG. 16.

(Capacitance Variation Between Opposite Wirings)

Incidentally, in the present technology, in the case where the variation in the wiring capacitance C_{fd-vsl} added between the FD wiring 131 and the VSL wiring 132 is larger than the variation in the drain-side overlap capacitance C_{gd} of the amplification transistor 214, the effect of reducing the variation becomes small. In view of the above, the wiring capacitance C_{fd-vsl} is formed with the opposite wiring Opp by which the variation in capacitance is reduced.

Further, in this opposite wiring Opp, although variation in values occurs due to misalignment or shape fluctuation at the time of pattern formation in the production process, the fluctuation rate of the capacitance decreases with respect to the same misalignment amount and the variation amount of the processing shape, as the distance between the opposite wirings is increased.

Therefore, in order to suppress the misalignment in the lithography process and the capacitance fluctuation due to the variation in the processed shape, it is desirable to increase the distance between the opposite wirings in the opposite wiring Opp as much as possible to extend the opposing length, in the same metal layer.

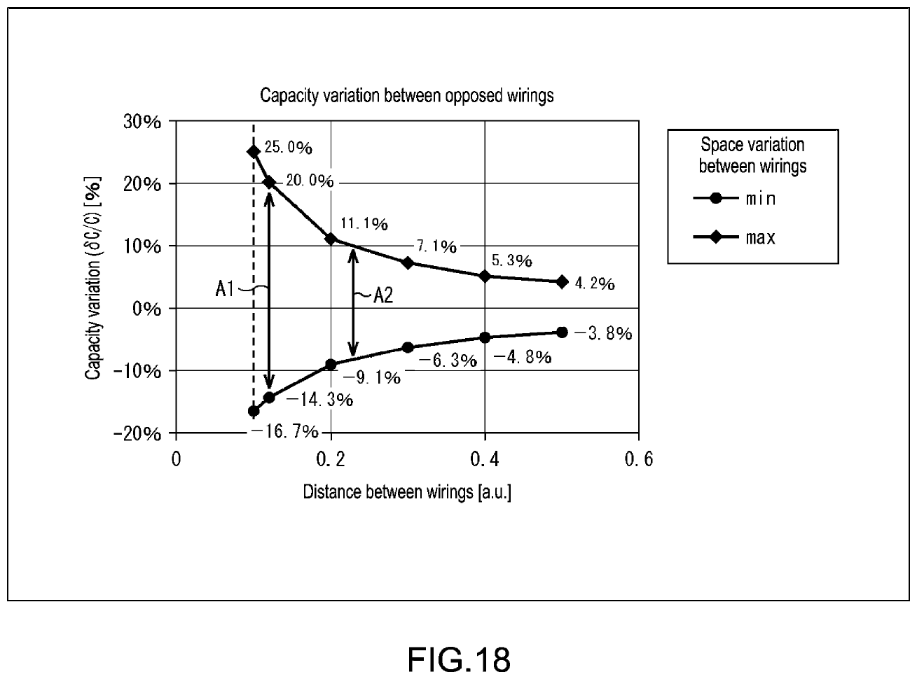

Note that FIG. 18 shows an example of the capacitance variation between the opposite wirings. Note that in FIG. 18, the horizontal axis represents the distance between the opposite wirings (a.u.), and the vertical axis represents the capacitance variation (δC/C). Further, a plurality of points are plotted on the line graph in the figure, but in the space variation between the opposite wirings, the maximum value is represented by a black rhombus and the minimum value is indicated by a black circle.

As shown in FIG. 18, the difference between the maximum value and the minimum value of the capacitance variation decreases as the distance between the opposite wirings of the FD wiring 131 and the VSL wiring 132 increases while the difference between the maximum value and the minimum value of the capacitance variation increases as the distance between the opposite wirings decreases.

For example, in the case where the capacitance variation in the minimum inter-wiring space on the design rule of the production process is represented by an arrow A1 in the figure, the maximum value of the capacitance variation is approximately 20.0%. In this case, the capacitance variation when opposite wirings are made at intervals twice the minimum inter-wiring space on the design rule can be represented by an arrow A2 in the figure.

Then, by making opposite wirings at intervals twice the minimum inter-wiring space on the design rule, the maximum value of the capacitance variation is reduced to approximately 10.0% as represented by the arrow A2 in the figure. That is, by doubling the interval between the opposite wirings, it is possible to reduce the maximum value of the capacitance variation from approximately 20.0% to approximately 10.0%, i.e., to be not more than approximately ½.

Since there is such a relationship, the inter-wiring space can be ensured as follows, for example.

That is, in the case where the opposite wiring Opp of the FD wiring 131 and the VSL wiring 132 is formed on the same metal layer, it is possible to significantly reduce the maximum value of the capacitance variation by ensuring the space between opposite wirings at least twice the minimum inter-wiring space on the design rule of the production process. This example corresponds to the opposite wiring between FD-VSL by the same metal layer (Metal-1) shown in FIG. 10, FIG. 13, and FIG. 16.

Further, in the case where the opposite wiring Opp of the FD wiring 131 and the VSL wiring 132 is formed on different metal layers, it is possible to significantly reduce the maximum value of the capacitance variation by ensuring the inter-wiring space with a footprint at least twice the minimum inter-wiring space of both metal layers. This example corresponds to the opposite wiring between FD-VSL by different metal layers (Metal-1, Metal-2) shown in FIG. 11, FIG. 14, and FIG. 17.

### 5. First Structural Example of Amplification Transistor

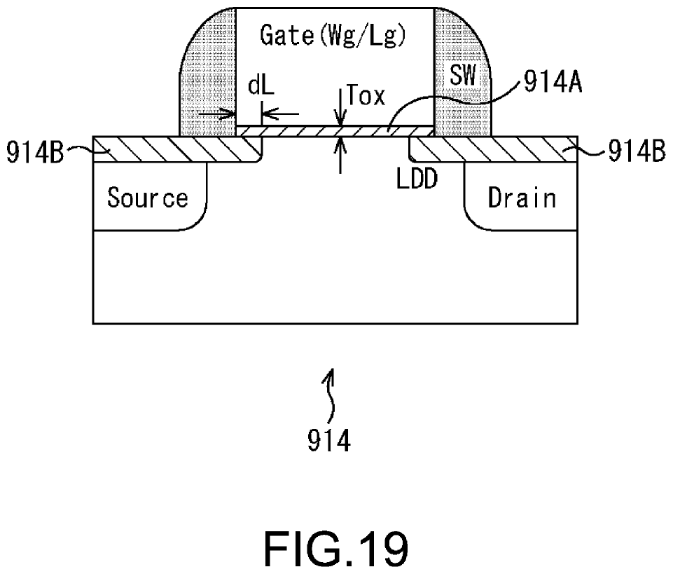

Note that FIG. 19 shows a cross-sectional structure in the source-drain direction of a general amplification transistor in a typical pixel. A general amplification transistor 914 has a structure in which an LDD (Lightly Doped Drain) 914B having a lower concentration than a source/drain is formed inside the source/drain, and the LDD 914B overlaps with a gate. Further, in the general amplification transistor 914, an oxide film 914A is formed on the gate.

In the general amplification transistor 914, a gate-drain capacitance C_{gd} is considered to be defined by a gate width (Wg), a film thickness (Tox) of the oxide film 914A, and an overlapping amount (dL) with the LDD 914B. Therefore, variation in gate-drain capacitance C_{gd} occurs due to production variation in the gate width (Wg), the film thickness (Tox) of the oxide film 914A, and the overlapping amount (dL) with the LDD 914B.

Meanwhile, it is known that noise of an amplification transistor caused by the current fluctuation of the amplification transistor is generally determined by a source-side channel, and that the noise is deteriorated in the case of an offset structure in which a source-side LDD is not sufficiently overlapping with a gate electrode. Further, it is generally known that since the noise has a property of being averaged according to the source-side channel width and is proportional to the inverse number (1/√Wg[S]) of the square root of a source-side channel width Wg[S], the noise is reduced when Wg[S] is increased and noise is increased when Wg[S] is decreased.

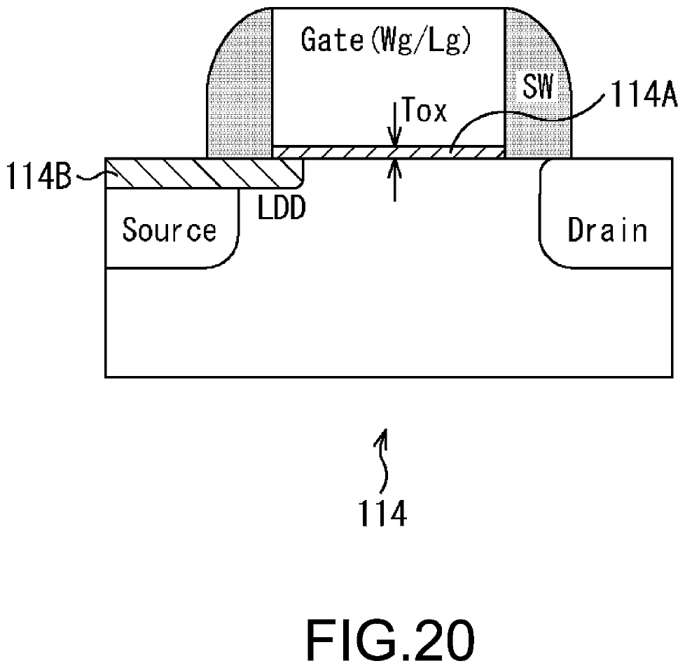

As shown in FIG. 20, since only the drain side has an offset structure and the LDD 114B is not injected under the gate of the drain side in the amplification transistor 114 to which an embodiment of the present technology is applied, the gap between the gate and the drain expands, and the source-side LDD sufficiently overlaps with the gate electrode at the same channel width (Wg[S]). Accordingly, it is possible to reduce only the gate-drain capacitance C_{gd} of the amplification transistor 114 that determines conversion efficiency while suppressing the increase in noise.

As a result, by increasing the channel width (Wg[S]) or expanding the capacity range of C_{fd-vsl} that can be added by the amount corresponding to the reduction in C_{gd} per unit channel width as a structure for achieving desired conversion efficiency, it is possible to improve PRNU by the effect of averaging.

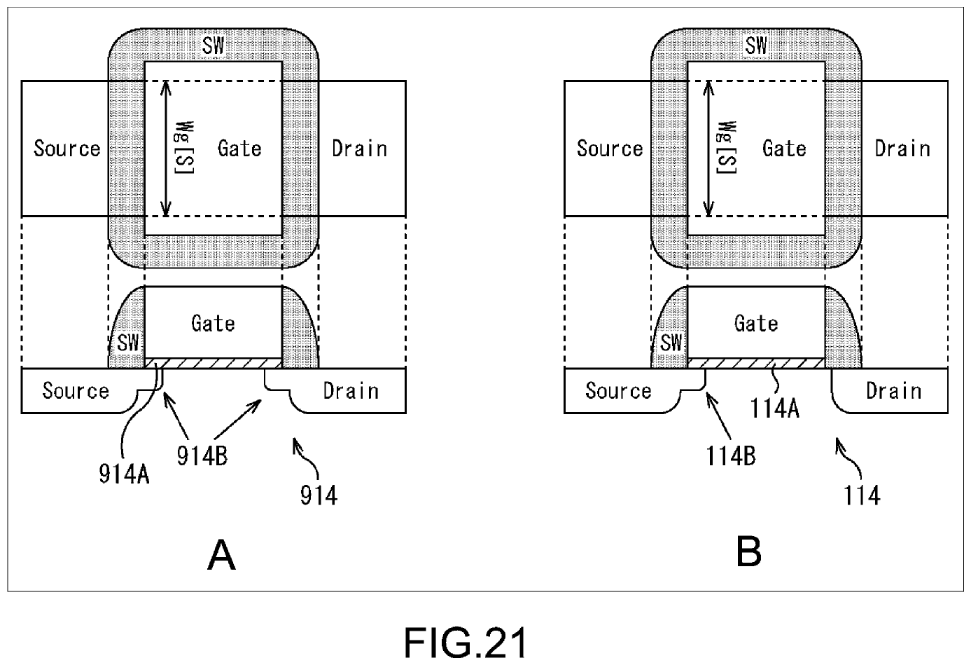

Note that FIG. 21 shows a cross-sectional view and a top view of each transistor, in order to compare the structure of the general amplification transistor 914 and the structure of the amplification transistor 114 shown in FIG. 20.

Specifically, FIG. 21A shows the structure of the general amplification transistor 914 in which the LDD 914B is injected under the gate and overlaps with the gate. Meanwhile, FIG. 21B shows the structure (asymmetric source-drain structure) of the amplification transistor 114 to which an embodiment of the present technology is applied in which only the drain side has an offset structure and the LDD 114B is not injected under the gate on the drain side.

As described above, it is possible to suppress the drain-side overlap capacitance C_{gd} by making the drain side of the amplification transistor 114 have an offset structure.

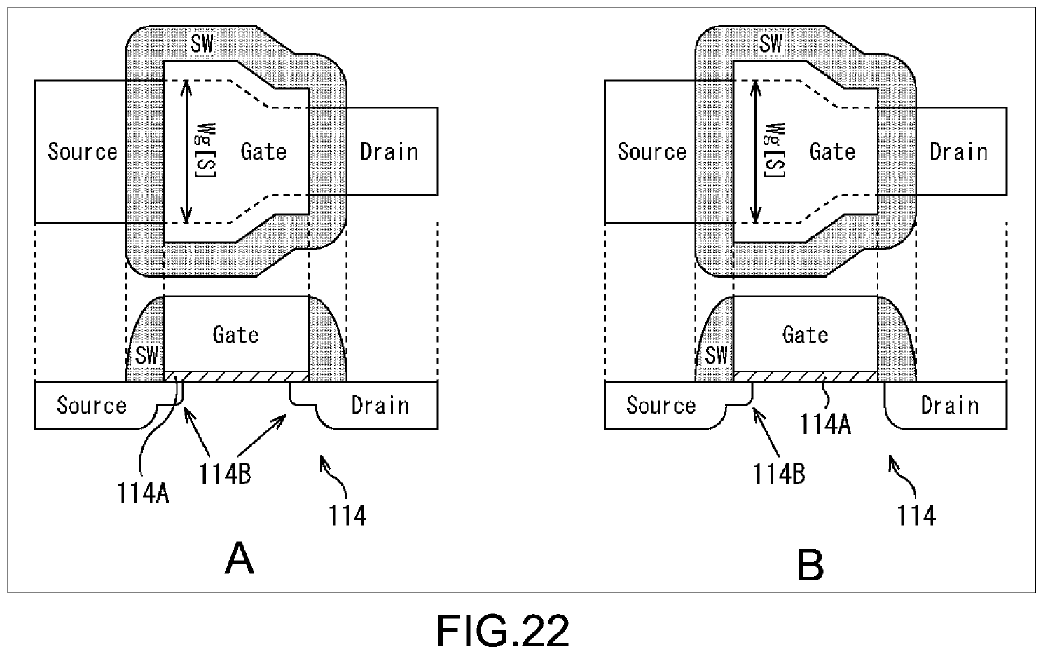

Note that as shown in FIG. 22, a structure in which the channel width on the drain side is narrower than the channel width on the source side (asymmetric source-drain structure) in the amplification transistor 114 may be adopted. In the case of adopting such a structure, a structure in which an LDD 114A is injected under the gate (FIG. 22A) as well as a structure in which only the drain side has an offset structure and the LDD 114B is not injected under the gate on the drain side (FIG. 22B) may be adopted.

As described above, by maintaining the source-side channel width, the degree of freedom of averaging by adding the capacitance C_{fd-vsl} increases while maintaining the noise characteristics equivalent to the same channel width. As a result, it is possible to reduce PRNU.

Further, even in the case where the amplification transistor 114 employs an offset structure or a structure in which the channel width on the drain side is narrower than the channel width on the source side, the feedback capacitance C_{FB} can be adjusted by adding the capacitance C_{fd-vsl} with the opposite wiring Opp of the FD wiring 131 connected to the floating diffusion 121 and the VSL wiring 132 connected to the vertical signal line 22, as described above.

That is, in the case where the amplification transistor 114 adopts an offset structure or a structure in which the channel width on the drain side is narrower than the channel width on the source side, whether to adjust the feedback capacitance C_{FB} by adding the wiring capacitance C_{fd-vsl} with the opposite wiring Opp of the FD wiring 131 and the VSL wiring 132 or to adjust the feedback capacitance C_{FB} only with the channel width (Wg[S]) is arbitrary.

Further, although the source-grounded reading has been described as an example here, for example, also in the case of applying to the differential reading, the amplification transistor 214 may have an offset structure or a structure in which the channel width on the drain side is narrower than the channel width on the source side.

(Effect of Present Technology)

In the present technology, improvement effect of PRNU by adjusting conversion efficiency and dispersing major variation factors of conversion efficiency is achieved by the wiring capacitance (opposite wiring capacitance) C_{fd-vsl} connected to the FD wiring 131 and the VSL wiring 132 without increasing the gate width (Wg) of the amplification transistor 114 (214) accompanied by the decrease in the PD occupancy rate, in the source-grounded pixel reading circuit 50 or the differential pixel reading circuit 70.

Further, in the case where the wiring capacitance C_{fd-vsl} added between the FD wiring 131 and the VSL wiring 132 is the same capacitance, by decreasing the capacitance per unit length of the opposite length as much as possible with increasing the opposite distance, and increasing an opposite length L by that amount, it is possible to further reduce the capacitance variation by the effect of being averaged in the L direction.

Hereinafter, details of reduction in PRNU due to dispersion of variation factors will be described.

In the case where the drain-side overlap capacitance C_{gd} of the gate width (Wg) of the amplification transistor 114 (214) and the wiring capacitance C_{fd-vsL} of the length L respectively have random variation with respect to Wg and L, the variation can be represented by the following formula (8) and formula (9).

$$\begin{matrix}[ Math . 8 ] & \\ \frac{{σ}_{{C}_{gd} ( Wg )}^{2}}{{〈 {C}_{gd} ( Wg ) 〉}^{2}} = ( \frac{α}{Wg} ) & ( 8 ) \\ [ Math . 9 ] & \\ \frac{{σ}_{{C}_{fd \text{-} vsl} ( L )}^{2}}{{〈 {C}_{fd \text{-} vsl} ( L ) 〉}^{2}} = ( \frac{β}{L} ) & ( 9 )\end{matrix}$$

At this time, the behavior of PRNU under the condition of C_{FB}=C_{gd}(Wg)+C_{fd-VSL}(L) will be considered.

Note that in the case where the ratio x of the drain-side overlap capacitance C_{gd}(Wg) to the feedback capacitance C_{FB} is defined as <C_{gd}(Wg)>=x×<C_{FB}>, the relationship of <C_{fd-VSL}(L)>=(1−x)×<C_{FB}> is established. Therefore, the following formula (10) is satisfied.

$$\begin{matrix}[ Math . 10 ] & \\ \begin{matrix}{PRNU}^{2} \approx \frac{{σ}_{η}^{2}}{{〈 η 〉}^{2}} \approx \frac{{σ}_{{C}_{FB}}^{2}}{{〈 {C}_{FB} 〉}^{2}} = \frac{{σ}_{{C}_{gd} ( Wg )}^{2} + {σ}_{{C}_{fd \text{-} vsl} ( L )}^{2}}{{\{ 〈 {C}_{gd} ( Wg ) 〉 + 〈 {C}_{fd \text{-} vsl} ( L ) 〉 \}}^{2}} \\ = \frac{( \frac{α}{Wg} ) \cdot {〈 {C}_{gd} ( Wg ) 〉}^{2} + ( \frac{β}{L} ) \cdot {〈 {C}_{fd \text{-} vsl} ( L ) 〉}^{2}}{{〈 {C}_{FB} 〉}^{2}} \\ = ( \frac{α}{Wg} ) \cdot {x}^{2} + ( \frac{β}{L} ) \cdot {( 1 - x )}^{2} \\ = \{ ( \frac{α}{Wg} ) + ( \frac{β}{L} ) \} \cdot {x}^{2} - 2 ( \frac{β}{L} ) \cdot x + ( \frac{β}{L} ) \\ = \{ ( \frac{α}{Wg} ) + ( \frac{β}{L} ) \} \cdot {\{ x - \frac{( \frac{β}{L} )}{( \frac{α}{Wg} ) + ( \frac{β}{L} )} \}}^{2} + \frac{( \frac{α}{Wg} ) \cdot ( \frac{β}{L} )}{( \frac{α}{Wg} ) + ( \frac{β}{L} )} \\ = \{ ( \frac{α}{Wg} ) + ( \frac{β}{L} ) \} \cdot {\{ x - \frac{( \frac{β}{L} )}{( \frac{α}{Wg} ) + ( \frac{β}{L} )} \}}^{2} + \frac{1}{( \frac{Wg}{α} ) + ( \frac{L}{β} )}\end{matrix} & ( 10 )\end{matrix}$$

Therefore, PRNU constantly takes the local minimum value shown in the following formula (12) under the condition of the formula (11).

$$\begin{matrix}[ Math . 11 ] & \\ 0 ≦ x = \frac{( β / L )}{( α / Wg ) + ( β + L )} ≦ 1 & ( 11 ) \\ [ Math . 12 ] & \\ {PRNU \vert}_{MIN}^{2} = \frac{1}{( Wg / α ) + ( L / β )} & ( 12 )\end{matrix}$$

Note that although C_{FB}=C_{gd}(Wg) in the case where x=1, and C_{FB}=C_{fd-VSL}(L) in the case where x=0, which represents that C_{FB} is formed with only any one of the components, the results shown by the above-mentioned formula (11) and formula (12) show that PRNU is minimized in the case where there are both components, as compared with the case where there is only any one of the components. Further, the ratio of the both components giving the minimum is uniquely determined by the target feedback capacitance C_{FB} or variation α and variation β per unit of each component.

In this way, by dividing the major variation factors into two capacitances of the drain-side overlap capacitance C_{gd} of the amplification transistor 114 (214) and the wiring capacitance C_{fd-VSL} added between the FD wiring 131 and the VSL wiring 132, it is possible to reduce PRNU.

6. Second Structural Example of Amplification Transistor

Incidentally, it is assumed that the pixel amplifier has a configuration in which the amplification transistor 114 is used in two current directions. For example, it is assumed that the pixel amplifier has a configuration in which the current flowing direction in the amplification transistor 114 differs in the differential mode and the SF mode. In the case of adopting such a configuration, various characteristics vary depending on the current direction. In this regard, the structure of the amplification transistor 114 corresponding to the variation in characteristics depending on the current flowing direction will be described below.

### First Structural Example

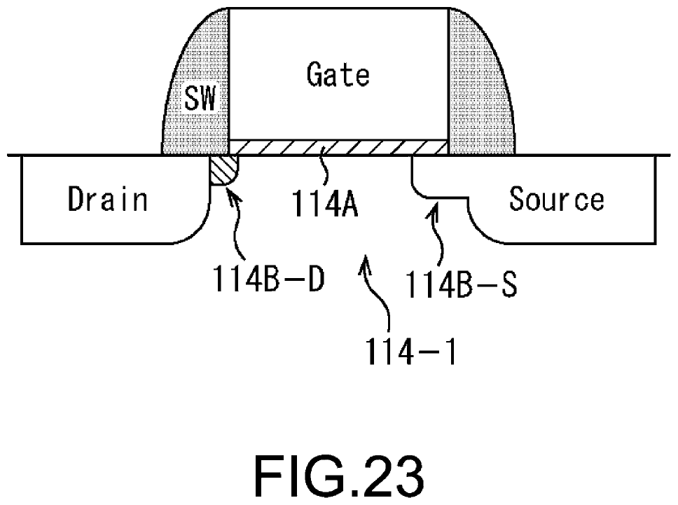

First, FIG. 23 shows a cross-sectional structure of an amplification transistor 114-1 as a first structural example. Note that the notation of the source and drain of the amplification transistor 114-1 shown in FIG. 23 corresponds to the terminal name in the current direction in the differential mode.

The amplification transistor 114-1 has a structure in which an LDD 114B-S is formed on the source side, an LDD 114B-D is formed on the drain side, and the LDD 114B-S and the LDD 114B-D overlap with the gate. Further, an oxide film 114A is formed on the gate.

The amplification transistor 114-1 has an LDD structure in which the LDD 114B-S and the LDD 114B-D are asymmetric in the left and right direction. Specifically, the LDD 114B-S on the source side is formed to spread below the gate and to be wider than the LDD 114B-D on the drain side.

The LDD 114B-S on the source side can be formed by using, for example, ion species having large (relatively large) diffusion such as phosphorus (P: Phos) as an impurity. Further, the LDD 114B-D can be formed by using, for example, ion species having small (relatively small) diffusion such as arsenic (As) as an impurity.

Note that in the case of performing the operation in the current direction in the differential mode (direction from the right side to the left side in the figure), the 1/f noise characteristics are favorable because the LDD 114B-S is formed on the source side, and also PRNU is favorable because the diffusion region of the LDD 114B-D on the drain side is formed to be small.

Meanwhile, in the case of assuming the operation in the current direction opposite to the current direction in the differential mode (direction from the left side to the right side in the figure), it is possible to reduce the influence of the HC (Hot Carrier) generated in the differential mode because the LDD regions of the LDD 114B-S and the LDD 114B-D are formed, and to prevent 1/f noise characteristics from being adversely affected.

### First Example of Production Method

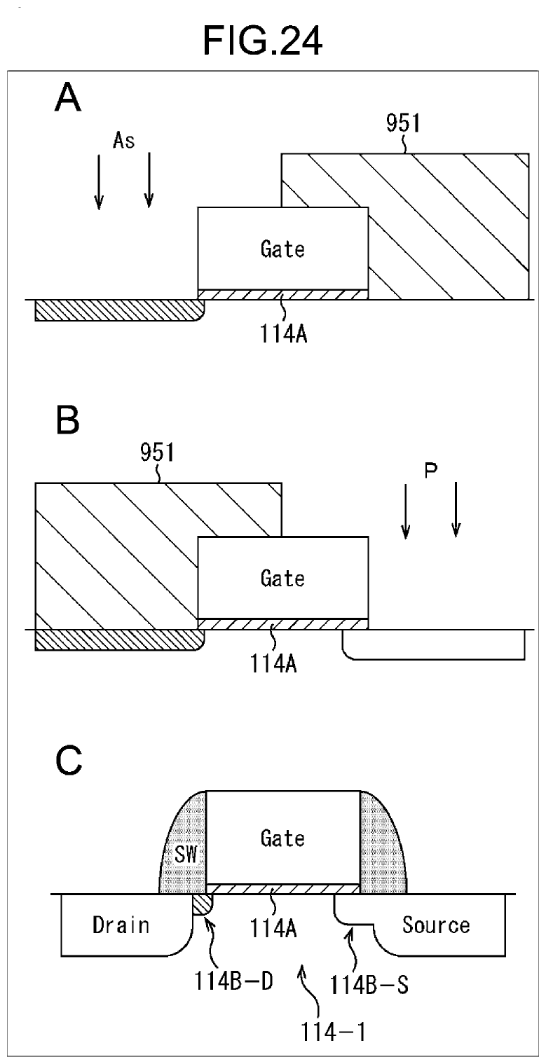

FIG. 24 shows flow of a method of producing the amplification transistor 114-1 shown in FIG. 23.

Note that although the ion-implantation process among all production processes will be mainly described in FIG. 24, processes such as a film formation process, a resist coating process, an exposure process, a development process, an etching process, and a resist removal process are performed as processes before and after the ion-implantation process.

In the ion-implantation process, first, as shown in FIG. 24A, a photoresist 951 coated on regions of a source and a part of a gate formed on a substrate serves as a protective material (mask), and thus, arsenic (As) is implanted into the region on the drain side by an ion-implantation apparatus.

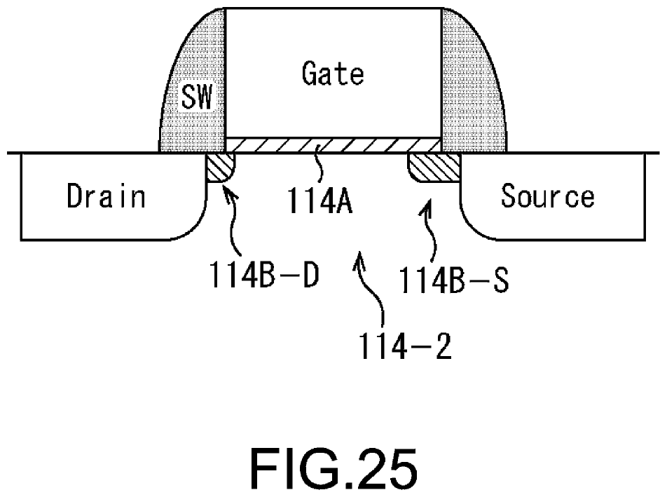

Next, as shown in FIG. 24B, the photoresist 951 coated on regions opposite to the regions shown in FIG. 25A, i.e., regions of the drain and a part of the gate formed on the substrate, serves as a protective material (mask), and thus, phosphorous (P) is implanted into the region on the source side by an ion-implantation apparatus.

As shown in FIG. 24C, the amplification transistor 114-1 having an LDD structure in which the LDD 114B-S on the source side and the LDD 114B-D on the drain side are asymmetric is produced by further performing processes such as the resist removal process after this ion-implantation process.

In the amplification transistor 114-1 produced in this way, the LDD 114B-S formed by using phosphorous (P) is formed to spread below the gate and to be wider than the LDD 114B-D on the drain side formed by using arsenic (As).

### Second Structural Example

Next, FIG. 25 shows a cross-sectional structure of an amplification transistor 114-2 as a second structural example.

In FIG. 25, the amplification transistor 114-2 has an asymmetric LDD structure in which the LDD 114B-S on the source side is formed to spread below the gate and to be wider than the LDD 114B-D on the drain side, similarly to the amplification transistor 114-1 shown in FIG. 23.

In the amplification transistor 114-2 shown in FIG. 25, the LDD 114B-S on the source side and the LDD 114B-D on the drain side can be formed by using ion species having small diffusion such as arsenic (As).

### Second Example of Production Method

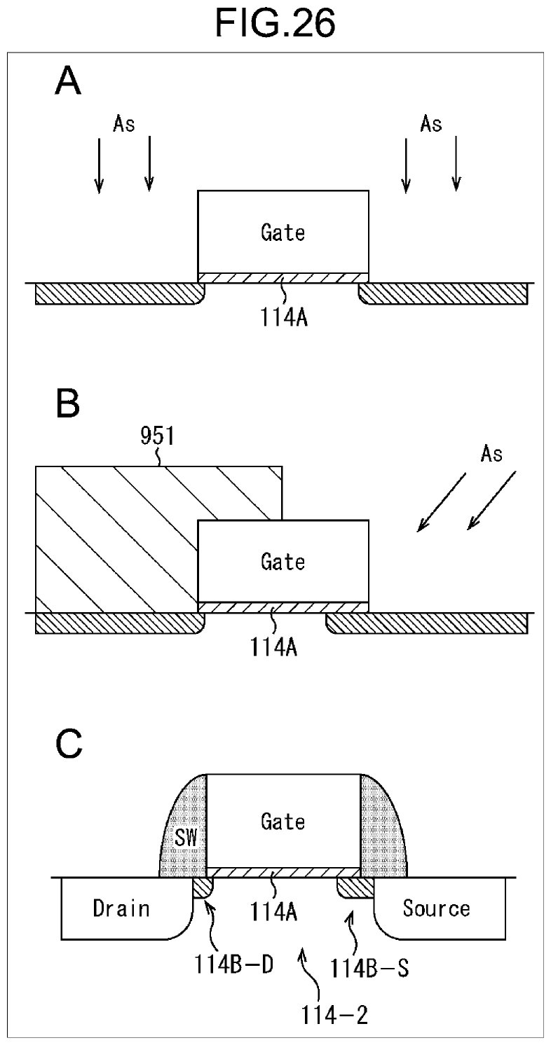

FIG. 26 shows flow of a method of producing the amplification transistor 114-2 shown in FIG. 25. Note that the ion-implantation process among all production processes will be mainly described.

In the ion-implantation process, first, as shown in FIG. 26A, arsenic (As) is implanted into regions of both a source and a drain formed on a substrate, by an ion-implantation apparatus.

Next, as shown in FIG. 26B, the photoresist 951 coated on regions of the drain and a part of a gate formed on the substrate serves as a protective material (mask), and thus, arsenic (As) is implanted into the region on the source side from the diagonally right direction.

As shown in FIG. 26C, the amplification transistor 114-2 having an LDD structure in which the LDD 114B-S on the source side and the LDD 114B-D on the drain side are asymmetric is produced by further performing processes such as the resist removal process after this ion-implantation process.

In the amplification transistor 114-2 produced in this way, the LDD 114B-S on the source side formed by using arsenic (As) is formed to spread below the gate and to be wider than the LDD 114B-D on the drain side formed by using arsenic (As).

Note that in this second production method, since arsenic (As) is implanted from the oblique direction in the ion-implantation process, directions of all pixel transistors need to be aligned.

### Third Structural Example

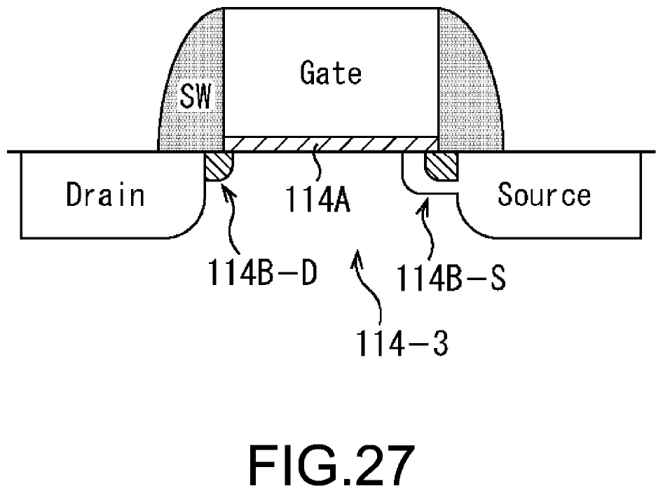

Finally, FIG. 27 shows a cross-sectional structure of an amplification transistor 114-3 as a third structural example.

In FIG. 27, the amplification transistor 114-3 has an asymmetric LDD structure in which the LDD 114B-S on the source side is formed to spread below the gate and to be wider than the LDD 114B-D on the drain side, similarly to the amplification transistor 114-1 shown in FIG. 23.

In the amplification transistor 114-3 shown in FIG. 27, the LDD 114B-D on the drain side is formed by using ion species having small diffusion such as arsenic (As). Meanwhile, in the LDD 114B-S on the source side, phosphorous (P) is formed so as to cover arsenic (As) formed inside.

### Third Example of Production Method

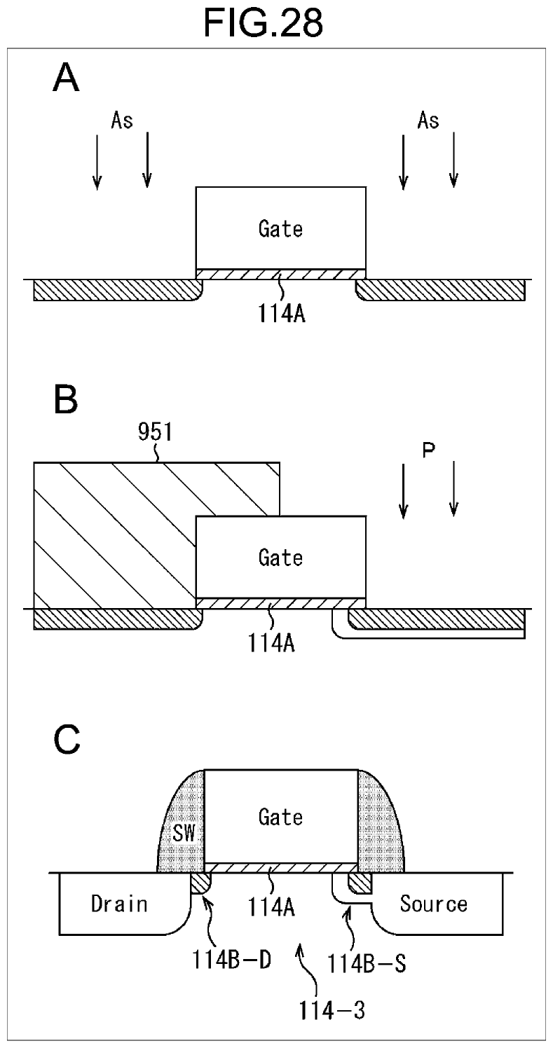

FIG. 28 shows flow of a method of producing the amplification transistor 114-3 shown in FIG. 27. Note that the ion-implantation process among all production processes will be mainly described.

In the ion-implantation process, first, as shown in FIG. 28A, arsenic (As) is implanted into regions of both a source and a drain formed on a substrate, by an ion-implantation apparatus.

Next, as shown in FIG. 28B, the photoresist 951 coated on regions of the drain and a part of a gate formed on the substrate serves as a protective material (mask), and thus, phosphorous (P) is implanted into the region on the source side.

As shown in FIG. 28C, the amplification transistor 114-3 having an LDD structure in which the LDD 114B-S on the source side and the LDD 114B-D on the drain side are asymmetric is produced by further performing processes such as the resist removal process after this ion-implantation process.

In the amplification transistor 114-3 produced in this way, the LDD 114B-S on the source side formed of arsenic (As) and phosphorous (P) covering the arsenic is formed to spread below the gate and to be wider than the LDD 114B-D on the drain side formed by using arsenic (As).

As the structure of the amplification transistor 114 corresponding to the variation in characteristics depending on the current flowing direction, three structures of the amplification transistors 114-1 to 114-3 have been described heretofore.

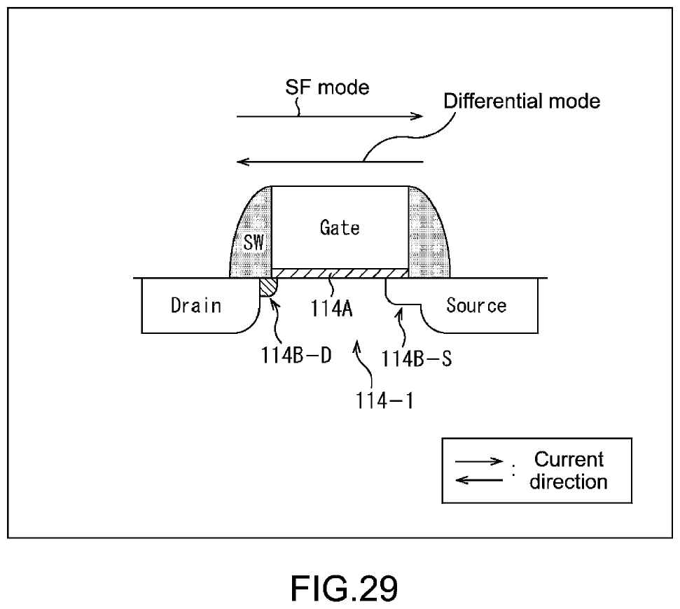

For example, by adopting the structure of the amplification transistor 114-1 as shown in FIG. 29, in the case of assuming the operation in the current direction in the differential mode (direction from the right side to the left side in the figure), favorable characteristics are achieved because the LDD 114B-S is provided on the source side, which is a noise source of the 1/f noise. Further, since the LDD 114B-D formed of arsenic (As) that is an example of ion species having low diffusion is provided on the drain side, it is possible to improve the PRNU characteristics, which cause a problem particularly in the case of high conversion efficiency, and also to achieve the effect of suppressing the HC deterioration.

Meanwhile, in the case of assuming the operation in the current direction in the SF mode (direction from the left side to the right side in the figure), it is possible to suppress the deterioration of the 1/f noise because the HC deterioration in the differential mode can be suppressed, and it is possible to maintain favorable original characteristics because the LDD regions of the LDD 114B-S and the LDD 114B-D are provided.

To summarize the above, in the pixel amplifier to which an embodiment of the present technology is applied, the following structures can be adopted as the structure of the amplification transistor 114, for example.

(A) MOSFET (Metal-Oxide-Semiconductor Field-Effect Transistor) structure in which a source and a drain are symmetrical and the following (a) or (b) is satisfied

(a) LDD is provided

(b) LDD is not provided

(B) MOSFET structure in which a source and a drain are asymmetric and any one of the following (c) to (e) is satisfied

(c) LDD is provided to only any one of the source or the drain

(d) LDD is provided to the source and the drain, and the LDD region on the source side is formed to spread below a gate and to be wider than the LDD region on the drain side

(e) LDD is provided to the source and the drain, and the LDD region on the drain side is formed to spread below a gate and to be wider than the LDD region on the source side

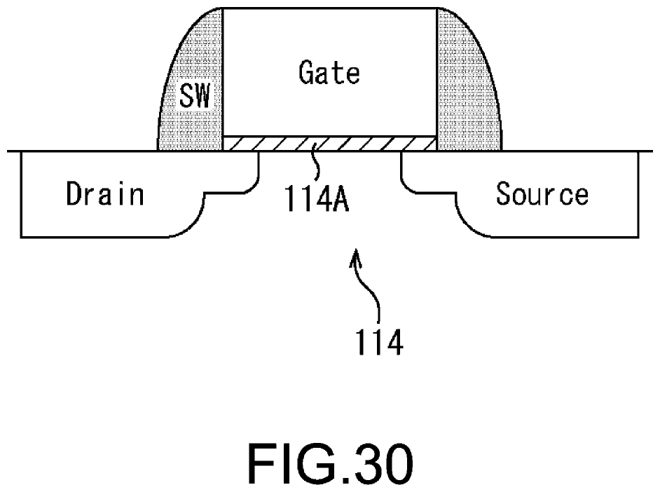

Note that as the structure of the amplification transistor 114 corresponding to the above-mentioned (A), for example, the structure shown in FIG. 30 can be adopted. In the amplification transistor 114 shown in FIG. 30, the source and the drain having a symmetric structure can be formed by using phosphorous (P) and arsenic (As), for example. Further, the structure of (d) of (B) corresponds to the structure of the above-mentioned amplification transistor 114 shown in FIGS. 23 to 29.

Note that in Japanese Patent Application Laid-open No. 2013-45878 (see FIG. 4), a structure in which the drain includes only a high-concentration impurity region and the source includes a high-concentration impurity region and a low-concentration impurity region (LDD) in combination is disclosed as the structure of the pixel transistor.

Further, in Japanese Patent Application Laid-open No. 2013-69913 (see FIG. 1), a structure in which an N layer having an impurity concentration lower than that of the LDD layer is formed in the LDD layer constituting the drain layer of the MOSFET having Halo to reduce the impurity concentration at the end of the drain region on the channel region side, and the LDD layer on the source region side is formed with a shallow junction depth concentration is disclosed as the structure of the pixel transistor.

However, since the technology disclosed in these two Patent Documents do not assume a case where the current flowing direction in the pixel transistor is bidirectional, the following problems may occur, for example.

Specifically, firstly, in the case of using, as a drain, the side in which no LDD is provided, HC deterioration may occur because the electric field intensity becomes stronger for the region including the LDD. Secondly, in the case of using, as a source, the side in which no LDD is provided, when there is the trap site generated by the above-mentioned HC, 1/f noise characteristics may be deteriorated.

Meanwhile, in the amplification transistor to which an embodiment of the present technology is applied, for example, in the case of assuming the current direction corresponding to the differential mode in a circuit system that realizes a plurality of functions by using the amplification transistor in which the current flowing direction is different, it is possible to cope with the variation in characteristics depending on the current flowing direction because the LDD region on the source side is formed to spread below the gate and to be wider than the LDD region on the drain side.

### 7. Modified Example

(Another Configuration Example of Pixel Amplifier)

FIG. 31 is a circuit diagram showing another configuration example of the differential inversion amplification pixel amplifier.

In the differential pixel reading circuit 80 shown in FIG. 31, portions corresponding to the differential pixel reading circuit 70 shown in FIG. 6 are denoted by the same reference symbols, and the description thereof will be appropriately omitted.

Specifically, in the differential pixel reading circuit 80 shown in FIG. 31, the read pixel 200 is configured similarly to the read pixel 200 shown in FIG. 6, and the reading-side vertical signal line 22S, the reading-side vertical reset input line 61S, and the reading-side vertical current supply line 62S are connected in a similar way to the configuration shown in FIG. 6.

Further, in the differential pixel reading circuit 80 shown in FIG. 31, although the reference pixel 300 is configured similarly to the reference pixel 300 shown in FIG. 6, the connection form of the reference-side vertical reset input line 61R out of the reference-side vertical signal line 22R, the reference-side vertical reset input line 61R, and the reference-side vertical current supply line 62R is different from the connection form shown in FIG. 6.

Specifically, in the differential pixel reading circuit 80 shown in FIG. 31, the reference-side vertical reset input line 61R is connected to the reference-side vertical signal line 22R, and to the floating diffusion 321 of the selected reference pixel 300, i.e., the input terminal of the amplification transistor 314. In other words, in the differential pixel reading circuit 80 shown in FIG. 31, the connection form of the reference-side vertical reset input line 61R is similar to that of the reading-side vertical reset input line 61S.

In the differential pixel reading circuit 80 having the above-mentioned configuration, the amplification transistor 214 of the read pixel 200 and the amplification transistor 314 of the reference pixel 300 constitute a differential amplifier, and thus, a voltage signal corresponding to the signal charge detected by the photoelectric conversion unit 211 of the read pixel 200 is output via the output terminal 73.

Further, as described above, also in the read pixel 200 or the reference pixel 300 of the differential pixel reading circuit 80, the wiring capacitance C_{fd-vsl} can be added by the opposite wiring Opp of the FD wiring 131 connected to the floating diffusion 221 (321) and the VSL wiring 132 connected to the vertical signal line 22S (22R), and the feedback capacitance C_{FB} can be adjusted.

(Backside Irradiation Type Structure)

Further, as described above, the CMOS image sensor 10 shown in FIG. 1 may be, for example, a backside irradiation type CMOS image sensor. By using the backside irradiation type CMOS image sensor, it is possible to further improve the degree of freedom of the pixel on the layout.

### 8. Configuration of Electronic Apparatus

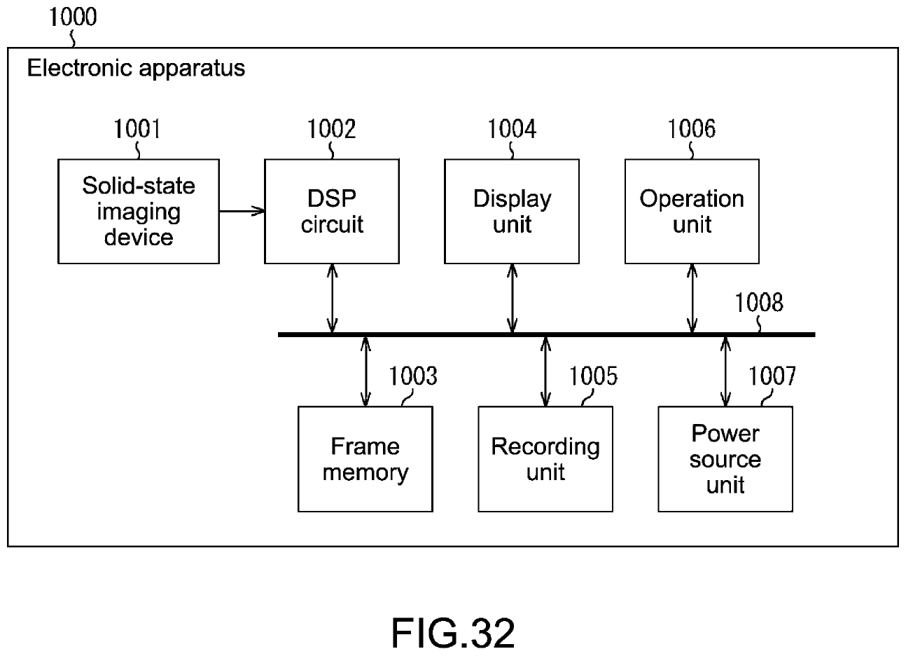

FIG. 32 is a block diagram showing a configuration example an electronic apparatus including a solid-state imaging device to which an embodiment of the present technology is applied.

An electronic apparatus 1000 is, for example, an electronic apparatus such as an imaging apparatus such as a digital still camera and a video camera, and a portable terminal apparatus such as a smartphone and a tablet terminal.

The electronic apparatus 1000 includes a solid-state imaging device 1001, a DSP circuit 1002, a frame memory 1003, a display unit 1004, a recording unit 1005, an operation unit 1006, and a power source unit 1007. Further, in the electronic apparatus 1000, the DSP circuit 1002, the frame memory 1003, the display unit 1004, the recording unit 1005, the operation unit 1006, and the power source unit 1007 are connected to each other via a bus line 1008.

The solid-state imaging device 1001 corresponds to the above-mentioned CMOS image sensor 10 (FIG. 1), and performs source-grounded reading, differential reading, and the like, on the plurality of pixels 100 (200, 300) arranged two-dimensionally the pixel array unit 11 (FIG. 1). Further, in each pixel, the wiring capacitance C_{fd-vsl} is added by the opposite wiring Opp of the FD wiring 131 connected to the floating diffusion (FD) and the VSL wiring 132 connected to the vertical signal line (VSL), and the feedback capacitance C_{FB} is adjusted.

The DSP circuit 1002 is a camera signal processing circuit that processes a signal supplied from the solid-state imaging device 1001. The DSP circuit 1002 outputs image data acquired by processing the signal from the solid-state imaging device 1001. The frame memory 1003 temporarily stores, in units of frames, the image data processed by the DSP circuit 1002.

The display unit 1004 includes, for example, a panel display apparatus such as a liquid crystal panel and an organic EL (Electro Luminescence) panel, and displays a moving image or a still image imaged by the solid-state imaging device 1001. The recording unit 1005 stores the image data of the moving image or still image imaged by the solid-state imaging device 1001 in a recording medium such as a semiconductor memory and a hard disk.

The operation unit 1006 outputs operation commands for various functions of the electronic apparatus 1000 in accordance with a user operation. The power source unit 1007 appropriately supplies various kinds of power sources as operation power sources for the DSP circuit 1002, the frame memory 1003, the display unit 1004, the recording unit 1005, and the operation unit 1006 to these supply targets.

The electronic apparatus 1000 is configured as described above. An embodiment of the present disclosure is applied to the solid-state imaging device 1001, as described above. Specifically, the CMOS image sensor 10 (FIG. 1) can be applied to the solid-state imaging device 1001. By applying an embodiment of the present technology to the solid-state imaging device 1001, in each pixel, since the wiring capacitance C_{fd-vsl} is added by the opposite wiring Opp of the FD wiring 131 and the VSL wiring 132 and the feedback capacitance C_{FB} is adjusted, it is possible to reduce the variation in conversion efficiency while reading signal charges with high conversion efficiency.

### 9. Usage Examples of Solid-State Imaging Device

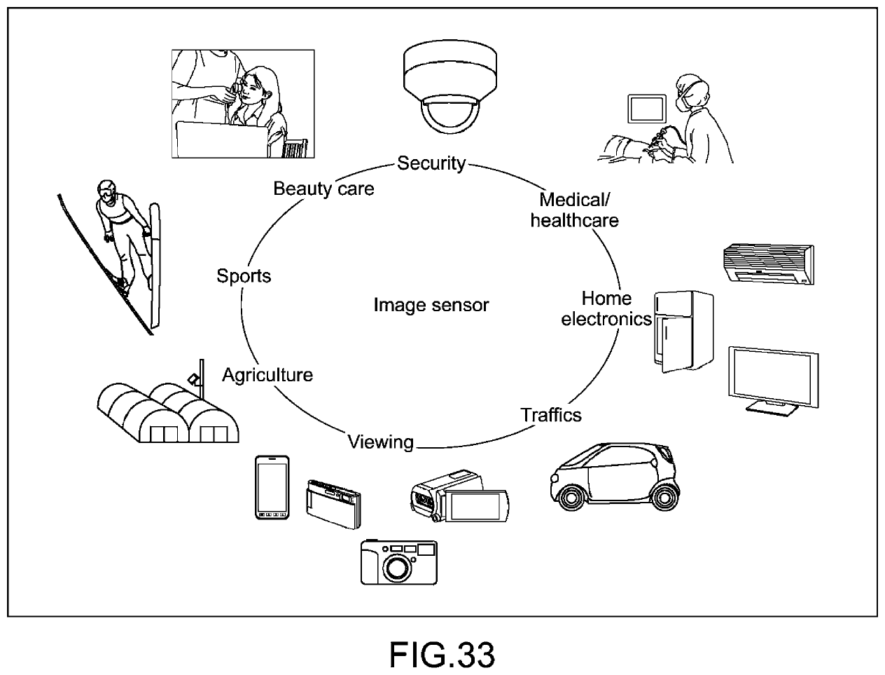

FIG. 33 is a diagram showing usage examples of a solid-state imaging device to which an embodiment of the present disclosure is applied.

The CMOS image sensor 10 (FIG. 1) can be used in various cases of sensing light such as visible light, infrared light, ultraviolet light, and X-rays as follows, for example. That is, as shown in FIG. 33, the CMOS image sensor 10 can be used for not only an apparatus used in the appreciation field for photographing images to be viewed but also apparatuses used in the traffic field, the home electronics field, the medical and healthcare field, the security field, the beauty care field, the sports field, and the agriculture field, for example.

Specifically, in the appreciation field, the CMOS image sensor 10 can be used for an apparatus for photographing images to be viewed (e.g., the electronic apparatus 1000 shown in FIG. 32), such as a digital camera, a smartphone, and a camera-equipped mobile phone.

In the traffic field, the CMOS image sensor 10 can be used for an apparatus used for traffic purposes, such as a car-mounted sensor that photographs front/rear/periphery/inside of an automobile, a surveillance camera that monitors running vehicles and roads, and a distance measurement sensor that measures distances among vehicles, for safe driving including automatic stop, recognition of a driver condition, and the like.

In the home electronics field, the CMOS image sensor 10 can be used for an apparatus used in home electronics such as a television receiver, a refrigerator, and an air conditioner, for photographing gestures of users and executing apparatus operations according to the gestures. Further, in the medical and healthcare field, the CMOS image sensor 10 can be used for an apparatus used for medical and healthcare purposes, such as an endoscope and an apparatus that performs blood vessel photographing by receiving infrared light.

In the security field, the CMOS image sensor 10 can be used for an apparatus used for security purposes, such as a surveillance camera for crime-prevention purposes and a camera for person authentication purposes. Further, in the beauty care field, the CMOS image sensor 10 can be used for an apparatus used for beauty care purposes, such as a skin measurement apparatus that photographs skins and a microscope that photographs scalps.

In the sports field, the CMOS image sensor 10 can be used for an apparatus used for sports purposes, such as an action camera and a wearable camera for sports purposes. Further, in the agriculture field, the CMOS image sensor 10 can be used for an apparatus for agriculture purposes, such as a camera for monitoring states of fields and crops.

### 10. Example of Application to Movable Object

The technology according to the present disclosure (the present technology) is applicable to various products. For example, the technology according to the present disclosure may be, for example, realized as a device mounted on any kind of movable objects such as a car, an electric car, a hybrid electric car, a motorcycle, a bicycle, a personal mobility, an aircraft, a drone, a ship, and a robot.

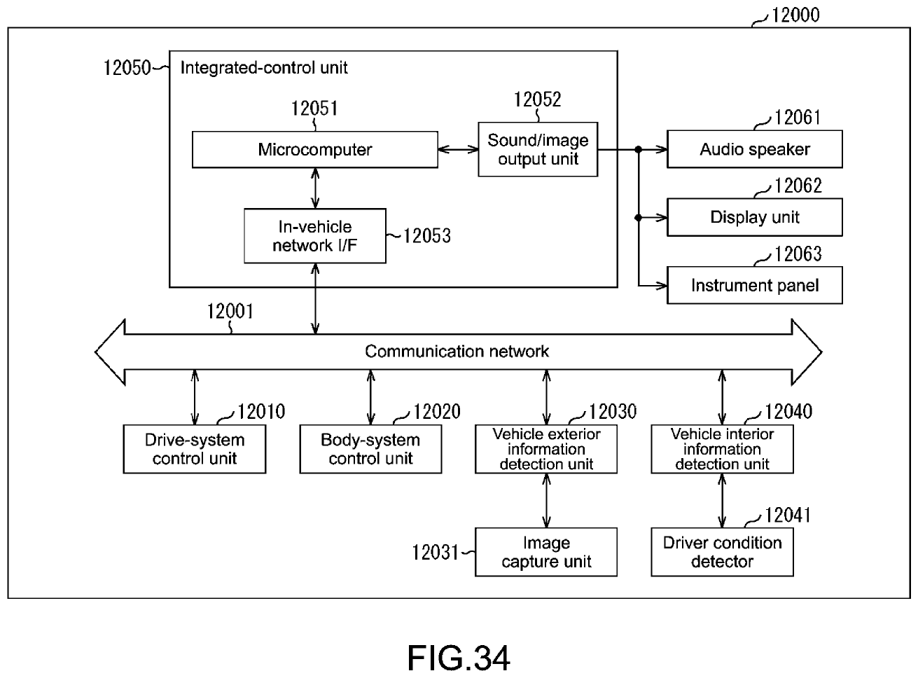

FIG. 34 is a block diagram showing an example of a schematic configuration of a vehicle control system, which is an example of a movable object control system to which the technology according to the present disclosure is applied.

A vehicle control system 12000 includes a plurality of electronic control units connected to each other via a communication network 12001. In the example of FIG. 34, the vehicle control system 12000 includes a drive-system control unit 12010, a body-system control unit 12020, a vehicle exterior information detection unit 12030, a vehicle interior information detection unit 12040, and an integrated-control unit 12050. Further, as the functional configuration of the integrated-control unit 12050, a microcomputer 12051, a sound/image output unit 12052, and an in-vehicle network interface (I/F) 12053 are shown.

The drive-system control unit 12010 executes various kinds of programs, to thereby control the operations of the devices related to the drive system of the vehicle. For example, the drive-system control unit 12010 functions as a control device that controls driving force generation devices such as an internal-combustion engine and a driving motor for generating a driving force of the vehicle, a driving force transmission mechanism for transmitting the driving force to wheels, a steering mechanism that adjusts the steering angle of the vehicle, a brake device that generates a braking force of the vehicle, and the like.

The body-system control unit 12020 executes various kinds of programs, to thereby control the operations of the various kinds devices equipped in a vehicle body. For example, the body-system control unit 12020 functions as a control device that controls a keyless entry system, a smart key system, a power window device, or various lamps such as head lamps, back lamps, brake lamps, side-turn lamps, and fog lamps. In this case, an electric wave transmitted from a mobile device in place of a key or signals from various switches may be input in the body-system control unit 12020. The body-system control unit 12020 receives the input electric wave or signal, and controls a door lock device, the power window device, the lamps, and the like of the vehicle.

The vehicle exterior information detection unit 12030 detects information outside the vehicle including the vehicle control system 12000. For example, an image capture unit 12031 is connected to the vehicle exterior information detection unit 12030. The vehicle exterior information detection unit 12030 causes the image capture unit 12031 to capture an environment image and receives the captured image. The vehicle exterior information detection unit 12030 may perform an object detection process of detecting a man, a vehicle, an obstacle, a sign, a signage on a road, or the like on the basis of the received image, or may perform a distance detection process on the basis of the received image.

The image capture unit 12031 is an optical sensor that receives light and outputs an electric signal corresponding to the amount of light received. The image capture unit 12031 may output the electric signal as an image or may output as distance measurement information. Further, the light that the image capture unit 12031 receives may be visible light or invisible light such as infrared light.

The vehicle interior information detection unit 12040 detects vehicle interior information. For example, a driver condition detector 12041 that detects the condition of a driver is connected to the vehicle interior information detection unit 12040. For example, the driver condition detector 12041 may include a camera that captures an image of a driver. The vehicle interior information detection unit 12040 may calculate the fatigue level or the concentration level of the driver on the basis of the detected information input from the driver condition detector 12041, and may determine whether the driver is sleeping.

The microcomputer 12051 may calculate the control target value of the driving force generation device, the steering mechanism, or the brake device on the basis of the vehicle interior/vehicle exterior information obtained by the vehicle exterior information detection unit 12030 or the vehicle interior information detection unit 12040, and may output a control command to the drive-system control unit 12010. For example, the microcomputer 12051 may perform coordinated control for the purpose of realizing the advanced driver assistance system (ADAS) function including avoiding a vehicle collision, lowering impacts of a vehicle collision, follow-up driving based on a distance between vehicles, constant speed driving, vehicle collision warning, a vehicle's lane departure warning, or the like.

Further, by controlling the driving force generation device, the steering mechanism, the brake device, or the like on the basis of information about the environment around the vehicle obtained by the vehicle exterior information detection unit 12030 or the vehicle interior information detection unit 12040, the microcomputer 12051 may perform coordinated control for the purpose of realizing self-driving, i.e., autonomous driving without the need of drivers' operations, and the like.

Further, the microcomputer 12051 may output a control command to the body-system control unit 12020 on the basis of vehicle exterior information obtained by the vehicle exterior information detection unit 12030. For example, the microcomputer 12051 may perform coordinated control including controlling the head lamps on the basis of the location of a leading vehicle or an oncoming vehicle detected by the vehicle exterior information detection unit 12030 and changing high beams to low beams, for example, for the purpose of anti-glare.

The sound/image output unit 12052 transmits at least one of a sound output signal and an image output signal to an output device, which is capable of notifying a passenger of the vehicle or a person outside the vehicle of information visually or auditorily. In the example of FIG. 34, an audio speaker 12061, a display unit 12062, and an instrument panel 12063 are shown as examples of the output devices. For example, the display unit 12062 may include at least one of an on-board display and a head-up display.

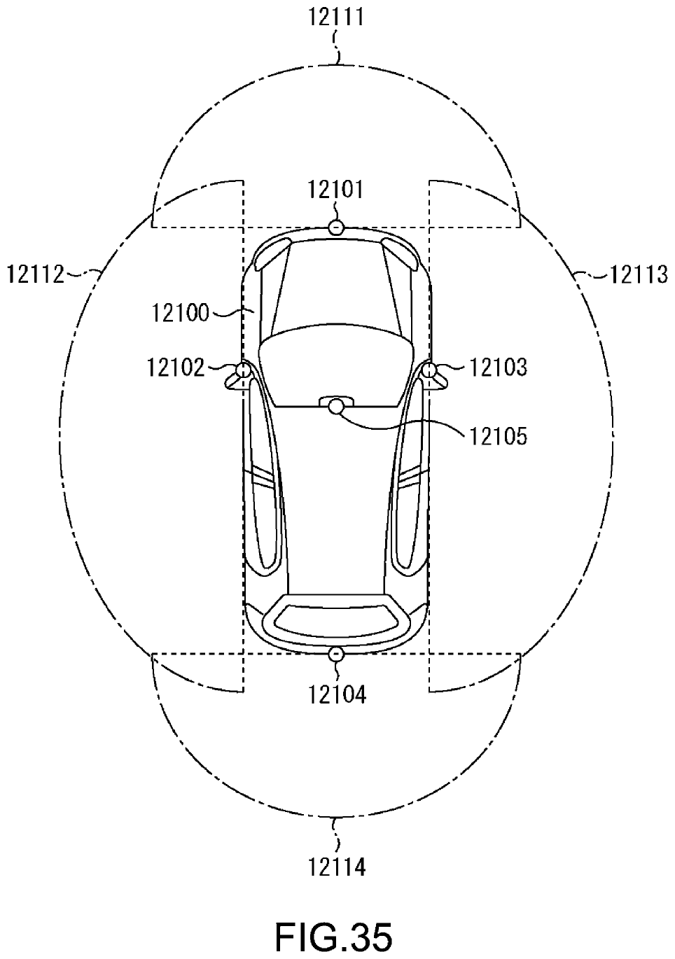

FIG. 35 is a diagram showing examples of mounting positions of the image capture units 12031.

In FIG. 35, a vehicle 12100 includes, as the image capture units 12031, image capture units 12101, 12102, 12103, 12104, and 12105.

For example, the image capture units 12101, 12102, 12103, 12104, and 12105 are provided at positions such as the front nose, the side-view mirrors, the rear bumper or the rear door, and an upper part of the windshield in the cabin of the vehicle 12100. Each of the image capture unit 12101 on the front nose and the image capture unit 12105 on the upper part of the windshield in the cabin mainly obtains an image of the front of the vehicle 12100. Each of the image capture units 12102 and 12103 on the side-view minors mainly obtains an image of a side of the vehicle 12100. The image capture unit 12104 on the rear bumper or the rear door mainly obtains an image of the rear of the vehicle 12100. The image capture unit 12105 provided on the upper part of the windshield in the cabin is mainly used for detecting a leading vehicle or detecting a pedestrian, an obstacle, a traffic light, a traffic sign, a lane, or the like.

Note that FIG. 35 shows examples of image capture ranges of the image capture units 12101 to 12104. The image capture range 12111 indicates the image capture range of the image capture unit 12101 on the front nose, the image capture ranges 12112 and 12113 indicate the image capture ranges of the image capture units 12102 and 12103 on the side-view minors, respectively, and the image capture range 12114 indicates the image capture range of the image capture unit 12104 on the rear bumper or the rear door. For example, by overlaying the image data captured by the image capture units 12101 to 12104 each other, a plane image of the vehicle 12100 as viewed from above is obtained.

At least one of the image capture units 12101 to 12104 may have a function of obtaining distance information. For example, at least one of the image capture units 12101 to 12104 may be a stereo camera including a plurality of image sensors or an image sensor including pixels for phase difference detection.

For example, by obtaining the distance between the vehicle 12100 and each three-dimensional (3D) object in the image capture ranges 12111 to 12114 and the temporal change (relative speed to the vehicle 12100) of the distance on the basis of the distance information obtained from the image capture units 12101 to 12104, the microcomputer 12051 may extract, as a leading vehicle, a 3D object which is especially the closest 3D object driving on the track on which the vehicle 12100 is driving at a predetermined speed (e.g., 0 km/h or more) in the direction substantially the same as the driving direction of the vehicle 12100. Further, by presetting a distance between the vehicle 12100 and a leading vehicle to be secured, the microcomputer 12051 may perform autobrake control (including follow-up stop control), automatic acceleration control (including follow-up start-driving control), and the like. In this way, it is possible to perform coordinated control for the purpose of realizing self-driving, i.e., autonomous driving without the need of drivers' operations, and the like.

For example, the microcomputer 12051 may sort 3D object data of 3D objects into motorcycles, standard-size vehicles, large-size vehicles, pedestrians, and the other 3D objects such as utility poles on the basis of the distance information obtained from the image capture units 12101 to 12104, extract data, and use the data to automatically avoid obstacles. For example, the microcomputer 12051 sorts obstacles around the vehicle 12100 into obstacles that a driver of the vehicle 12100 can see and obstacles that it is difficult for the driver to see. Then, the microcomputer 12051 determines a collision risk, which indicates a hazard level of a collision with each obstacle. When the collision risk is a preset value or more and when there is a possibility of a collision occurrence, the microcomputer 12051 may perform driving assistance to avoid a collision, in which the microcomputer 12051 outputs warning to the driver via the audio speaker 12061 or the display unit 12062, or mandatorily reduces the speed or performs collision-avoidance steering via the drive-system control unit 12010.

At least one of the image capture units 12101 to 12104 may be an infrared camera that detects infrared light. For example, the microcomputer 12051 may recognize a pedestrian by determining whether or not images captured by the image capture units 12101 to 12104 include the pedestrian. The method of recognizing a pedestrian includes, for example, the step of extracting characteristic points in the images captured by the image capture units 12101 to 12104 being infrared cameras, and the step of performing the pattern matching process with respect to a series of characteristic points indicating an outline of an object, to thereby determine whether or not the object is a pedestrian. Where the microcomputer 12051 determines that the images captured by the image capture units 12101 to 12104 include a pedestrian and recognizes the pedestrian, the sound/image output unit 12052 controls the display unit 12062 to display a rectangular contour superimposed on the recognized pedestrian to emphasize the pedestrian. Further, the sound/image output unit 12052 may control the display unit 12062 to display an icon or the like indicating a pedestrian at a desired position.

The above describes an example of the vehicle control system to which the technology according to the present disclosure may be applied. The technology according to the present disclosure may be applied to the image capture unit 12031 having the above-mentioned configuration. Specifically, the CMOS image sensor 10 shown in FIG. 1 can be applied to the image capture unit 12031. The image capture unit 12031, to which the technology according to the present disclosure is applied, is effective for more accurately recognizing an obstacle such as a pedestrian, because variation in conversion efficiency can be reduced while reading signal charges with high conversion efficiency, a high SN ratio is achieved, and a captured image with higher quality can be obtained.

Note that embodiments of the present technology are not limited to the above-mentioned embodiments but various modifications can be made without departing from the gist of the present technology.

It should be noted that the present technology can also take the following configurations.

(1)

A solid-state imaging device, including:

a pixel array unit, pixels being two-dimensionally arranged in the pixel array unit, the pixels each including a photoelectric conversion unit, in which

the pixels each include a first wiring and a second wiring opposed to each other, the first wiring being connected to a floating diffusion, a charge detected by the photoelectric conversion unit being transferred to the floating diffusion, the second wiring being connected to a vertical signal line for outputting a signal from the floating diffusion, a feedback capacitance of a pixel amplifier being adjusted by capacitance addition by opposite wirings including the first wiring and the second wiring.

(2)

The solid-state imaging device according to (1) above, in which the pixel amplifier is a source-grounded inversion amplification pixel amplifier.

(3)

The solid-state imaging device according to (1) above, in which the pixel amplifier is a differential inversion amplification pixel amplifier.

(4)

The solid-state imaging device according to any one of (1) to (3) above, in which the capacitance addition is performed with a wiring capacitance by the opposite wirings connected to an electrode of the floating diffusion and the vertical signal line, and variation in the feedback capacitance is suppressed by dispersing the feedback capacitance into two components of a drain-side overlap capacitance of an amplification transistor of the pixel and the wiring capacitance.

(5)

The solid-state imaging device according to any one of (1) to (3) above, in which a capacitance added to an unselected pixel is disconnected from the vertical signal line and variation in the feedback capacitance is suppressed by performing the capacitance addition with a wiring capacitance by the opposite wirings connected to an electrode of the floating diffusion and a diffusion layer between an amplification transistor and a selection transistor of the pixel.

(6)

The solid-state imaging device according to any one of (1) to (3) above, in which variation in the feedback capacitance is suppressed by performing the capacitance addition with a wiring capacitance by the opposite wirings connected to an electrode of the floating diffusion and a drain-side electrode of a reset transistor of the pixel.

(7)

The solid-state imaging device according to any one of (4) to (6) above, in which the opposite wirings are formed on the same metal layer.

(8)

The solid-state imaging device according to (7) above, in which space between the opposite wirings is not less than twice a minimum space between wirings in design in a production process.

(9)

The solid-state imaging device according to any one of (4) to (6) above, in which the opposite wirings are formed on different metal layers.

(10)

The solid-state imaging device according to (9) above, in which space between the opposite wirings has a footprint that is not less than twice a minimum space between wirings in the metal layers.

(11)

The solid-state imaging device according to any one of (4) to (6) above, in which the amplification transistor of the pixel has an asymmetric source-drain structure, an LDD (Lightly Doped Drain) region being formed only on a source side in the asymmetric source-drain structure.

(12)

The solid-state imaging device according to any one of (4) to (6) above, in which the amplification transistor of the pixel has an asymmetric source-drain structure, a channel width on a drain side being narrower than a channel width on a source side in the asymmetric source-drain structure.

(13)

The solid-state imaging device according any one of (4) to (6) above, in which the amplification transistor of the pixel has an asymmetric source-drain structure, a channel width on a drain side being narrower than a channel width on a source side in the asymmetric source-drain structure, an LDD region being formed only on a source side in the asymmetric source-drain structure.

(14)

The solid-state imaging device according to any one of (4) to (6) above, in which the amplification transistor of the pixel has a structure in which an overlapping amount of an LDD region on a source side with a gate and an overlapping amount of an LDD region on a drain side with the gate differ.

(15)

The solid-state imaging device according to (14) above, in which in the amplification transistor of the pixel, a current flowing direction differs depending on a mode.

(16)

The solid-state imaging device according to (15) above, in which the pixels are each capable of performing differential reading and source follower reading as a reading method, and the mode includes a first mode and a second mode, the differential mode being performed in the first mode, the source follower reading being performed in the second mode.

(17)

The solid-state imaging device according to (16) above, in which the amplification transistor of the pixel has a structure in which the LDD region on the source side spreads below the gate to be wider than the LDD region on the drain side, assuming the current flowing direction corresponding to the first mode.

(18)

The solid-state imaging device according to any one of (14) to (17) above, in which a first impurity and a second impurity include different impurities, the LDD region on the source side being formed of the first impurity, the LDD region on the drain side being formed of the second impurity.

(19)

The solid-state imaging device according to (18) above, in which the LDD region on the source side is formed of the first impurity having diffusion larger than that of the second impurity, and

the LDD region on the drain side is formed of the second impurity having diffusion smaller than that of the first impurity.

(20)

The solid-state imaging device according to any one of (1) to (19) above, in which the pixels are each capable of performing differential reading and source follower reading as a reading method, the solid-state imaging device further including a switching unit configured to switch the reading method of the pixel between the differential reading and the source follower reading.

(21)

The solid-state imaging device according to any one of (1) to (20) above, in which the solid-state imaging device is a backside irradiation type solid-state imaging device.

(22)

An electronic apparatus, including:

a solid-state imaging device including a pixel array unit, pixels being two-dimensionally arranged in the pixel array unit, the pixels each including a photoelectric conversion unit, in which

the pixels each include a first wiring and a second wiring opposed to each other, the first wiring being connected to a floating diffusion, a charge detected by the photoelectric conversion unit being transferred to the floating diffusion, the second wiring being connected to a vertical signal line for outputting a signal from the floating diffusion, a feedback capacitance of a pixel amplifier being adjusted by capacitance addition by opposite wirings including the first wiring and the second wiring.

(23)

A solid-state imaging device, including:

a pixel array unit, pixels being two-dimensionally arranged in the pixel array unit, the pixels each including a photoelectric conversion unit, in which

the amplification transistor of the pixel has an asymmetric source-drain structure, an LDD region being formed only on a source side in the asymmetric source-drain structure.

(24)

A solid-state imaging device, including:

a pixel array unit, pixels being two-dimensionally arranged in the pixel array unit, the pixels each including a photoelectric conversion unit, in which

the amplification transistor of the pixel has an asymmetric source-drain structure, a channel width on a drain side being narrower than a channel width on a source side in the asymmetric source-drain structure.

(25)

The solid-state imaging device according to (24) above, in which

the amplification transistor of the pixel has an asymmetric source-drain structure, a channel width on a drain side being narrower than a channel width on a source side in the asymmetric source-drain structure, an LDD region being formed only on a source side in the asymmetric source-drain structure.

(26)

An electronic apparatus, including:

a solid-state imaging device, including

a pixel array unit, pixels being two-dimensionally arranged in the pixel array unit, the pixels each including a photoelectric conversion unit, in which

the amplification transistor of the pixel has an asymmetric source-drain structure, an LDD region being formed only on a source side in the asymmetric source-drain structure.

(27)

A solid-state imaging device, including:

a pixel array unit, pixels being two-dimensionally arranged in the pixel array unit, the pixels each including a photoelectric conversion unit, in which

the amplification transistor of the pixel has a structure in which an overlapping amount of an LDD region on a source side with a gate and an overlapping amount of an LDD region on a drain side with the gate differ.

(28)

The solid-state imaging device according to (27) above, in which

in the amplification transistor of the pixel, a current flowing direction differs depending on a mode.

(29)

The solid-state imaging device according to (28) above, in which

the pixels are each capable of performing differential reading and source follower reading as a reading method, and

the mode includes a first mode and a second mode, the differential mode being performed in the first mode, the source follower reading being performed in the second mode.

(30)

The solid-state imaging device according to (29) above, in which

the amplification transistor of the pixel has a structure in which the LDD region on the source side spreads below the gate to be wider than the LDD region on the drain side, assuming the current flowing direction corresponding to the first mode.

(31)

The solid-state imaging device according to any one of (27) to (30) above, in which a first impurity and a second impurity include different impurities, the LDD region on the source side being formed of the first impurity, the LDD region on the drain side being formed of the second impurity.

(32)

The solid-state imaging device according to (31) above, in which the LDD region on the source side is formed of the first impurity having diffusion larger than that of the second impurity, and the LDD region on the drain side is formed of the second impurity having diffusion smaller than that of the first impurity.

(33)

An electronic apparatus, including:

a solid-state imaging device including a pixel array unit, pixels being two-dimensionally arranged in the pixel array unit, the pixels each including a photoelectric conversion unit, in which

the amplification transistor of the pixel has a structure in which an overlapping amount of an LDD region on a source side with a gate and an overlapping amount of an LDD region on a drain side with the gate differ.

It should be understood by those skilled in the art that various modifications, combinations, sub-combinations and alterations may occur depending on design requirements and other factors insofar as they are within the scope of the appended claims or the equivalents thereof.

(34)

An imaging device including:

a plurality of pixels, a pixel of the plurality of pixels comprising:

a first wiring coupled to a floating diffusion;

a second wiring opposed to the first wiring such that a wiring capacitance is formed;

a pixel amplifier with a feedback capacitance that is based on the wiring capacitance; and

a vertical signal line arranged to output a signal from the floating diffusion, in which the wiring capacitance is formed between the floating diffusion and the vertical signal line.

(35)

The imaging device according to (34), in which the pixel includes:

a photodetector comprising a cathode and an anode; and

a first transistor comprising a source and a drain, in which the source of the first transistor is coupled to the cathode of the photodetector and the drain of the first transistor is coupled to the floating diffusion.

(36)

The imaging device according to (35), wherein the pixel further includes:

a second transistor comprising a source and a drain, wherein the source of the second transistor is coupled to an output of the pixel amplifier and the drain of the second transistor is coupled to the vertical signal line.

(37)

The imaging device according to (34), in which the first wiring and the second wiring are disposed within a same wiring layer of the pixel.

(38)

The imaging device according to (34), wherein the first wiring is disposed within a first wiring layer of the pixel and the second wiring is disposed within a second wiring layer of the pixel, in which the first wiring layer and the second wiring layer are at different depths within the pixel.

(39)

The imaging device according to (38), in which the first wiring is disposed within the first wiring layer and the second wiring layer of the pixel.

(40)

The imaging device according to (34), in which a first portion of the first wiring is parallel to the second wiring and a second portion of the first wiring is perpendicular to the second wiring in a top view.

(41)

An imaging device including a plurality of pixels, a pixel of the plurality of pixels including:

a first wiring coupled to a floating diffusion;

a second wiring opposed to the first wiring such that a wiring capacitance is formed;

a pixel amplifier with a feedback capacitance that is based on the wiring capacitance;

a vertical signal line arranged to output a signal from the floating diffusion;

a first transistor comprising a source and a drain; and

a second transistor comprising a source and a drain, in which the source of the second transistor is coupled to an output of the pixel amplifier and the drain of the second transistor is coupled to the vertical signal line,

in which the wiring capacitance is formed between the floating diffusion and the source of the second transistor.

(42)

The imaging device according to (41), in which the pixel further comprises a photodetector comprising a cathode and an anode, in which the source of the first transistor is coupled to the cathode of the photodetector and the drain of the first transistor is coupled to the floating diffusion.

(43)

The imaging device according to (41), in which the first wiring and the second wiring are disposed within a same wiring layer of the pixel.

(44)

The imaging device according to (41), in which the first wiring is disposed within a first wiring layer of the pixel and the second wiring is disposed within a second wiring layer of the pixel, in which the first wiring layer and the second wiring layer are at different depths within the pixel.

(45)

The imaging device according to (44), in which the first wiring is disposed within the first wiring layer and the second wiring layer of the pixel.

(46)

The imaging device according to (45), in which a first portion of the first wiring is parallel to at least one portion of the second wiring and a second portion of the first wiring is perpendicular to the at least one portion of the second wiring in a top view.

(47)

An imaging device including a plurality of pixels, a pixel of the plurality of pixels including:

a first wiring coupled to a floating diffusion;

a second wiring opposed to the first wiring such that a wiring capacitance is formed;

a pixel amplifier with a feedback capacitance that is based on the wiring capacitance;

a vertical signal line arranged to output a signal from the floating diffusion;

a first transistor comprising a source and a drain;

a second transistor comprising a source and a drain, in which the source of the second transistor is coupled to an output of the pixel amplifier and the drain of the second transistor is coupled to the vertical signal line; and

a third transistor comprising a source and a drain, in which the source of the third transistor is coupled to the floating diffusion and the drain of the third transistor is coupled to a reset line, in which the wiring capacitance is formed between the floating diffusion and the drain of the third transistor.

(48)

The imaging device according to (47), in which the pixel further comprises a photodetector comprising a cathode and an anode, in which the source of the first transistor is coupled to the cathode of the photodetector and the drain of the first transistor is coupled to the floating diffusion.

(49)

The imaging device according to (47), in which the first wiring and the second wiring are disposed within a same wiring layer of the pixel.

(50)

The imaging device according to (47), wherein the first wiring is disposed within a first wiring layer of the pixel and the second wiring is disposed within a second wiring layer of the pixel, wherein the first wiring layer and the second wiring layer are at different depths within the pixel.

(51)

The imaging device according to (47), in which a first portion of the first wiring is parallel to at least one portion of the second wiring and a second portion of the first wiring is perpendicular to the at least one portion of the second wiring in a top view.

(52)

An amplifier including a transistor that includes:

a gate; and

an asymmetric source-drain structure including:

a source region including a first region including an impurity with a first concentration; and a second region including an impurity with a second concentration larger than the first concentration;

a drain region comprising a third region including an impurity with a third concentration larger than the first concentration.

(53)

The amplifier according to (52), in which the drain region does not include a fourth region including an impurity with a fourth concentration less than the third concentration.

(54)

The amplifier according to (52), in which the drain region comprises a fourth region including an impurity with a fourth concentration less than the third concentration.

(55)

The amplifier according to (54), in which a drain impurity of the fourth region is different from a source impurity of the first region.

(56)

The amplifier according to (55), in which the drain impurity is arsenic and the source impurity is phosphorous.

(57)

The amplifier according to (54), in which a drain impurity of the fourth region is the same as a source impurity of the first region.

(58)

The amplifier according to (57), in which the drain impurity and the source impurity are selected from the group consisting of arsenic or phosphorous.

(59)

The amplifier according to (57), in which the first region extends under the gate farther than the fourth region extends under the gate.

(60)

The amplifier according to (54), in which a drain impurity of the fourth region is a single type of impurity and a source impurity of the first region comprises a plurality of impurity types.

(61)

The amplifier according to (60), in which the drain impurity consists of arsenic and the source impurity comprises arsenic and phosphorous.

(62)

The amplifier according to (54), in which the first region has a thickness in a depth direction that is greater than a thickness in the depth direction of the fourth region.

(63)

The amplifier according to (52), in which a channel width of the drain region is less than a channel width of the source region.

(64)

The amplifier according to (63), in which the gate is asymmetric.

(65)

The amplifier according to (64), in which a width of the gate nearest the source region is greater than a width of the gate nearest the drain region.

1. An imaging device comprising:
a plurality of pixels, a pixel of the plurality of pixels comprising:
a first wiring coupled to a floating diffusion;
a second wiring opposed to the first wiring such that a wiring capacitance is formed;
a pixel amplifier with a feedback capacitance that is based on the wiring capacitance; and
a vertical signal line arranged to output a signal from the floating diffusion,
wherein the wiring capacitance is formed between the floating diffusion and the vertical signal line.

2. The imaging device of claim 1, wherein the pixel comprises:
a photodetector comprising a cathode and an anode; and
a first transistor comprising a source and a drain, wherein the source of the first transistor is coupled to the cathode of the photodetector and the drain of the first transistor is coupled to the floating diffusion.

3. The imaging device of claim 2, wherein the pixel further comprises:
a second transistor comprising a source and a drain, wherein the source of the second transistor is coupled to an output of the pixel amplifier and the drain of the second transistor is coupled to the vertical signal line.

4. The imaging device of claim 1, wherein the first wiring and the second wiring are disposed within a same wiring layer of the pixel.

5. The imaging device of claim 1, wherein the first wiring is disposed within a first wiring layer of the pixel and the second wiring is disposed within a second wiring layer of the pixel, wherein the first wiring layer and the second wiring layer are at different depths within the pixel.

6. The imaging device of claim 5, wherein the first wiring is disposed within the first wiring layer and the second wiring layer of the pixel.

7. The imaging device of claim 1, wherein a first portion of the first wiring is parallel to the second wiring and a second portion of the first wiring is perpendicular to the second wiring in a top view.

8. An imaging device comprising:
a plurality of pixels, a pixel of the plurality of pixels comprising:
a first wiring coupled to a floating diffusion;
a second wiring opposed to the first wiring such that a wiring capacitance is formed;
a pixel amplifier with a feedback capacitance that is based on the wiring capacitance;
a vertical signal line arranged to output a signal from the floating diffusion;
a first transistor comprising a source and a drain; and
a second transistor comprising a source and a drain, wherein the source of the second transistor is coupled to an output of the pixel amplifier and the drain of the second transistor is coupled to the vertical signal line,
wherein the wiring capacitance is formed between the floating diffusion and the source of the second transistor.

9. The imaging device of claim 8, wherein the pixel further comprises a photodetector comprising a cathode and an anode, wherein the source of the first transistor is coupled to the cathode of the photodetector and the drain of the first transistor is coupled to the floating diffusion.

10. The imaging device of claim 8, wherein the first wiring and the second wiring are disposed within a same wiring layer of the pixel.

11. The imaging device of claim 8, wherein the first wiring is disposed within a first wiring layer of the pixel and the second wiring is disposed within a second wiring layer of the pixel, wherein the first wiring layer and the second wiring layer are at different depths within the pixel.

12. The imaging device of claim 11, wherein the first wiring is disposed within the first wiring layer and the second wiring layer of the pixel.

13. The imaging device of claim 8, wherein a first portion of the first wiring is parallel to at least one portion of the second wiring and a second portion of the first wiring is perpendicular to the at least one portion of the second wiring in a top view.

14. An imaging device comprising:
a plurality of pixels, a pixel of the plurality of pixels comprising:
a first wiring coupled to a floating diffusion;
a second wiring opposed to the first wiring such that a wiring capacitance is formed;
a pixel amplifier with a feedback capacitance that is based on the wiring capacitance;
a vertical signal line arranged to output a signal from the floating diffusion;
a first transistor comprising a source and a drain;
a second transistor comprising a source and a drain, wherein the source of the second transistor is coupled to an output of the pixel amplifier and the drain of the second transistor is coupled to the vertical signal line; and
a third transistor comprising a source and a drain, wherein the source of the third transistor is coupled to the floating diffusion and the drain of the third transistor is coupled to a reset line,
wherein the wiring capacitance is formed between the floating diffusion and the drain of the third transistor.

15. The imaging device of claim 14, wherein the pixel further comprises a photodetector comprising a cathode and an anode, wherein the source of the first transistor is coupled to the cathode of the photodetector and the drain of the first transistor is coupled to the floating diffusion.

16. The imaging device of claim 14, wherein the first wiring and the second wiring are disposed within a same wiring layer of the pixel.

17. The imaging device of claim 14, wherein the first wiring is disposed within a first wiring layer of the pixel and the second wiring is disposed within a second wiring layer of the pixel, wherein the first wiring layer and the second wiring layer are at different depths within the pixel.

18. The imaging device of claim 14, wherein a first portion of the first wiring is parallel to at least one portion of the second wiring and a second portion of the first wiring is perpendicular to the at least one portion of the second wiring in a top view.

19. An amplifier comprising:
a transistor comprising:
a gate; and
an asymmetric source-drain structure comprising:
a source region comprising:
a first region including an impurity with a first concentration; and
a second region including an impurity with a second concentration larger than the first concentration;
a drain region comprising:
a third region including an impurity with a third concentration larger than the first concentration.

20. The amplifier of claim 19, wherein the drain region does not include a fourth region including an impurity with a fourth concentration less than the third concentration.

21. The amplifier of claim 19, wherein the drain region comprises a fourth region including an impurity with a fourth concentration less than the third concentration.

22. The amplifier of claim 21, wherein a drain impurity of the fourth region is different from a source impurity of the first region.

23. The amplifier of claim 22, wherein the drain impurity is arsenic and the source impurity is phosphorous.

24. The amplifier of claim 21, wherein a drain impurity of the fourth region is the same as a source impurity of the first region.

25. The amplifier of claim 24, wherein the drain impurity and the source impurity are selected from the group consisting of arsenic or phosphorous.

26. The amplifier of claim 24, wherein the first region extends under the gate farther than the fourth region extends under the gate.

27. The amplifier of claim 21, wherein a drain impurity of the fourth region is a single type of impurity and a source impurity of the first region comprises a plurality of impurity types.

28. The amplifier of claim 27, wherein the drain impurity consists of arsenic and the source impurity comprises arsenic and phosphorous.

29. The amplifier of claim 21, wherein the first region has a thickness in a depth direction that is greater than a thickness in the depth direction of the fourth region.

30. The amplifier of claim 19, wherein a channel width of the drain region is less than a channel width of the source region.

31. The amplifier of claim 30, wherein the gate is asymmetric.

32. The amplifier of claim 31, wherein a width of the gate nearest the source region is greater than a width of the gate nearest the drain region.
